(19) United States
(12) Patent Application Publication
(10) Pub. No.: US 2022/0037407 A1
(43) Pub. Date: Feb. 3, 2022

(54) MULTI-JUNCTION OPTOELECTRONIC DEVICE COMPRISING DEVICE INTERLAYER

(71) Applicant: OXFORD UNIVERSITY INNOVATION LIMITED, Oxford (GB)

(72) Inventors: Henry James Snaith, Oxford (GB); Suhas Mahesh, Oxford (GB)

(21) Appl. No.: 17/413,774

(22) PCT Filed: Dec. 13, 2019
(86) PCT No.: PCT/GB2019/053550

§ 371 Date: Jun. 14, 2021

(30) Foreign Application Priority Data
Dec. 14, 2018 (GB) 1820427.1

(51) Int. Cl. H01L 27/30; H01L 31/0224; H01L 31/0725

(52) U.S. Cl. CPC H01L 27/302; H01L 31/0725; H01L 31/022475

(57) ABSTRACT

The invention relates to a multi-junction device comprising a) a first photoactive region comprising a layer of a first photoactive material, b) a second photoactive region comprising a layer of a second photoactive material, and c) a charge recombination layer disposed between the first and second photoactive regions, wherein the charge recombination layer comprises a charge recombination layer material, wherein one of the first and second photoactive materials comprises at least one A/M/X material; wherein the other of the first and second photoactive materials comprises at least one A/M/X material or a compound which is a photoactive semiconductor other than an A/M/X material; wherein each A/M/X material is a crystalline compound of formula (I) [A]ₐ[M]_{b}[X]_{c} wherein: [A] comprises one or more A cations; [M] comprises one or more M cations which are metal or metalloid cations; [X] comprises one or more X anions; a is a number from 1 to 6; b is a number from 1 to 6; and c is a number from 1 to 18; and wherein the charge recombination layer material has a refractive index, η(λ), at a wavelength, λ, of at least 2, wherein λ is a wavelength of from 500 nm to 1200 nm.

### FIELD OF THE INVENTION

The invention provides a multi-junction device comprising a first photoactive region comprising a layer of a first photoactive material, a second photoactive region comprising a layer of a second photoactive material, and a charge recombination layer disposed between the first and second photoactive regions.

### BACKGROUND TO THE INVENTION

In order to provide perovskite solar cells that reach thermodynamically limiting efficiencies, device stacks have to be simultaneously electronically and optically optimized. While electronic optimization to reduce open-circuit voltage (V_{oc}) and fill-factor losses receives much attention, optical optimization to increase short-circuit current density (J_{sc}) is somewhat neglected. Single junction cells can usually be optimized by brute force optimization of layer thickness. However, due to the multitude of layers in multi-junction devices, complex optical modeling is required to maximize the light absorption and hence efficiency [Hörantner et al., ACS Energy Letters 2, no. 10 (2017): 2506-13].

A multi-junction device consists of two or more absorbers of different bandgaps, stacked such that each absorber absorbs photons from a different part of the spectrum. This helps reduce the energy lost as thermalisation of carriers, increasing the absorbed solar light to electrical power conversion efficiency (PCE). The simplest multi-junction device is a tandem device, with two absorbers as shown in FIG. 1. For monolithic tandem cells, where all the sub cells are processed on top of each other and the electrical power is extracted via two terminals, the two sub-cells are electrically connected in series through a recombination layer.

As an alternative to the two-terminal monolithic approach for tandem solar cells, it is possible to fabricate the two solar cells separately upon separate substrates, and subsequently stack them together. This is often referred to as a four-terminal stacked tandem cell. However, this four terminal stacked approach has several disadvantages. One disadvantage is the requirement for at least three highly transparent and highly conductive electrodes, which increases cost and reduces optical transmission from the top cell into the bottom cell. A further disadvantage of the four terminal stacked approach is that it is necessary to fabricate two completely separate modules and have two completely separate electronic circuits for the two sub cells, further increasing cost. In contrast, the two terminal monolithic approach only requires the deposition of additional layers, and all costs associated with turning the deposited multiple thin films layers into a module will remain similar to a single junction module.

For perovskite solar cells, based on metal halide perovskites, there have been two successful strategies which have delivered functional monolithic two-terminal tandem cells. One strategy is to use physical vapor deposition of the perovskite absorber layers, alongside physical vapor deposition of the charge extraction and recombination layers. Via these means, very thin charge transport and recombination layers can be processed (˜5 to 20 nm in thickness). Since these thicknesses are much smaller than a quarter of the wavelength of solar light over the visible to near infrared region of the spectrum, optical interference and reflection within and between these layers is not highly problematic. A further advantage of physical vapor deposition is that there is no need to consider dissolution of the underlying layers due to solvent interactions. However, to date, the best quality perovskite absorbers are processed via solution processing, which is simpler to perform than vapor deposition. One problem with solution processing is that the solvents used to deposit the layers onto the device stack may degrade the previously deposited layers, leading to reduced device performance. Solvents such as dimethylformamide (DMF), dimethyl sulfoxide (DMSO), γ-butyrolactone and dimethylacetamide (DMA) are often used to deposit perovskite precursors to form the photoactive layers. However, these solvents have a tendency to remove pre-existing organic layers during device production. Also, if a perovskite layer is already present in the device stack, these solvents may degrade the perovskite layer unless steps are taken to prevent solvent penetration into the device stack. One option to inhibit solvent penetration is to use the recombination layer as a physical barrier, which prevents the solvents used to deposit the second cell from dissolving the layers that form the first cell underneath. There therefore exists a need to develop recombination layers with minimal optical interference and reflection that are also substantial enough to prevent solvent damage to underlying layers during device fabrication.

A second approach to making functional tandem cells, which enables the use of solution processed perovskite layers, employs an intermediate dense metal oxide layer of indium oxide tin oxide (ITO) as the recombination layer. This ITO intermediate layer has two functions: in the first instance it acts as a physical barrier to the solvent used to process the second perovskite absorber layer, enabling the use of multiple solution processed layers. In the second instance, it acts as the semitransparent electrical charge recombination layer, enabling monolithic serial interconnection of the two sub-cells. However, these layers result in significant reflection losses from the infrared region of the spectrum (above 750 nm), therefore, the current densities generated from the lower band gap cells in such a device are much lower than desired. There therefore exists a need to provide recombination layers that are better able to prevent reflection losses in the infrared part of the spectrum to maximize the performance of both the top and bottom cells in a multi-junction device.

Hörantner et al. suggest completely removing the ITO layer, and maximizing the current density in the perovskite tandem cell by having extremely thin electron and hole charge extraction layers. However, in reality this would be impractical, since there would be no suitable solvent barrier for the subsequently processed perovskite absorber layer. As discussed above, when there is no (or a very thin) barrier between the perovskite absorber layers, the solvent used to deposit the second perovskite layer may dissolve the underlying perovskite layer and possibly any other organic n-type or p-type layers present. This is impractical for device fabrication.

It is well known empirically (“Moss Rule”) that in semiconductors, refractive index n increases as bandgap E_{g} decreases [Hervé and L. K. J. Vandamme, Infrared Physics and Technology 35, no. 4 (1994): 609-15].

n⁴·E_{g}=constant

Hence in a multi-junction cell, light is expected to encounter sharp changes in refractive index as it moves successively through absorbers of changing bandgap. This index mismatch causes light to be reflected out of the stack, causing a reduction in the absorbed sun light in the rear sub cells and a subsequent reduction in current density. Every absorber in the stack, except the widest bandgap, is subject to this reflection loss. The reflection is also wavelength dependent. The main reflection losses in an all perovskite tandem cell which employs an indium tin oxide (ITO) recombination layer are at the top cell-ITO-Bottom cell interface. The reflection varies between little to severe depending on the phase difference between the waves reflected from the top and the bottom interfaces of the recombination layer. For the wavelengths where interference is destructive, very little reflection is seen. Heavy reflection is seen at wavelengths where interference is constructive. The same constructive interference is identified as the cause behind the large dip commonly seen in the external quantum efficiency (EQE) spectra of tandem bottom cells [Giles E. et al. Eperon, Science 354, no. 6314 (2016): 861-65]. The presence of the dip, even in optically modelled EQE spectra in literature, shows that it is a purely optical phenomenon. [Maximilian T. Hörantner et al., ACS Energy Letters 2, no. 10 (2017): 2506-13]. The elimination of this reflection loss is highly desirable in the quest for the optically optimized perovskite multi-junction device.

While all perovskite multi-junction devices suffer this loss, the loss is particularly large in tandem cells, where the two absorber bandgaps are spaced most widely apart, compared to other multijunction cells. All perovskite tandem cells exhibit this large mismatch in refractive index at the top absorber-ITO and ITO-bottom absorber interfaces:

There is therefore a need to optimize the optical properties of multi-junction devices, in order that higher short-circuit current densities can be achieved.

Eperon et al. [Giles E. et al. Eperon, Science 354, no. 6314 (2016): 861-65] discloses tandem perovskite-perovskite photovoltaics using a layer of sputter coated ITO as the recombination layer. As noted above, whilst such layers do act as barriers to solvent attack on the underlying perovskite layer during device fabrication, they also result in significant losses due to reflection within the device.

Hörantner et al. [Maximilian T. Hörantner et al., ACS Energy Letters 2, no. 10 (2017): 2506-13] discusses modelling to optimize the band gap and thickness of the layers in tandem devices. Hörantner et al suggests that the best improvements to device efficiency could be obtained by removing the ITO recombination layer completely. As noted above, this is not practical for solution processed devices where the recombination layer acts as a barrier to protect the underlying layers when the second cell is manufactured.

Mazarella et al. [Mazarella. L. et al. Optics Express, Vol. 26, No. 10 (2018), A487] relates to optical simulations for perovskite/silicon heterojunction tandem solar cells. Jäger et al. [Jäger. K. et al., Optics Express, Vol. 25, No. 12 (2017), A473] relates to optimizing the thickness of the layers in silicon/perovskite tandem solar cells. This document also focuses on use of an ITO recombination layer

There therefore exists a need for a recombination layer that has optimal optical properties, that can readily be deposited via conventional means such as sputter coating or solution-processing and which can act as a barrier layer to prevent damage to the underlying structure for deposition of further (solution processed) layers above, and which has the requisite electrical properties to allow charge recombination.

### SUMMARY OF THE INVENTION

Here, the inventors have established a new solution to this problem. They have realized that replacing the ITO interlayer with a semitransparent material which has an optimised refractive index (preferably intermediate to that of the top and bottom perovskite absorber layers), is capable of satisfying both requirements for dense material of suitable thickness for solvent-blocking, while enhancing the forward transfer of light (minimizing reflectance losses) into the rear cell.

Table 1 shows the change in refractive index, or mismatch in refractive index, at different interfaces in the solar cells for perovskite (perov) sub cells with other perovskite sub cells, silicon (Si) sub cells and copper indium gallium (selenide) sulfide (CIGS) sub cells. For the type of Tandem cell, the brackets give the band gap of the absorber material in the different sub cells. Next to the refractive index mismatch the value in brackets is the wavelength of light at which this mismatch is estimated.

| | Top Absorber- | ITO-Bottom |
|---|---|---|
| Tandem | ITO Mismatch | Absorber Mismatch |
| Perov-Perov | 0.7 (850 nm) | 1.0 (850 nm) |
| (1.8 eV-1.2 eV) | | |
| Perov-Si | 0.82 (850 nm) | 2.08 (850 nm) |
| (1.65 eV-1.1 eV) | | |
| Perov-CIGS | 0.7 (850 nm) | 1.5 (850 nm) |
| (1.8 eV-1.2 eV) | | |

In devices that use an ITO interlayer, the mismatch in refractive index between the ITO and the perovskite absorber layers, and the fact that the ITO must have a certain thickness in order to perform its role as solvent-blocking-layer, results in significant optical interference within the device stack, and significant reflection losses from the infrared region of the spectrum. As a result, the current density generated from the lower band gap cells in such a device are much lower than desired. By providing a device with an interlayer which has an optimised refractive index, this problem is avoided and the power conversion efficiency (PCE) may be increased as the access of light (generally of longer wavelength) to the bottom cell (usually the lower bandgap cell) is improved.

Unexpectedly, the inventors also reveal that such index-matched devices are less sensitive to variations in angle of incidence, thus making such devices better suited to real world applications where the angle of incidence will vary depending on the time of day, the time of year, the weather (cloud cover or direct sunlight), humidity, dust and location. Such cells are therefore well suited to use in locations where diffuse light (as opposed to direct sunlight) may dominate, for instance in countries where overcast weather is common.

A further unexpected finding in relation to the devices of the invention is that the performance of such devices is significantly less sensitive to the expected random variations in layer thicknesses during manufacturing, in comparison to cells employing a known ITO interlayer. The present invention therefore overcomes a number of problems noted for existing multi-junction devices.

Accordingly, the present invention provides a multi-junction device comprising

a) a first photoactive region comprising a layer of a first photoactive material,

b) a second photoactive region comprising a layer of a second photoactive material, and

c) a charge recombination layer disposed between the first and second photoactive regions, wherein the charge recombination layer comprises a charge recombination layer material, wherein one of the first and second photoactive materials comprises at least one A/M/X material; wherein the other of the first and second photoactive materials comprises at least one A/M/X material or a compound which is a photoactive semiconductor other than an A/M/X material; wherein each A/M/X material is a crystalline compound of formula (I)

[A]ₐ[M]_{b}[X]_{c} (I)

wherein: [A] comprises one or more A cations; [M] comprises one or more M cations which are metal or metalloid cations; [X] comprises one or more X anions; a is a number from 1 to 6; b is a number from 1 to 6; and c is a number from 1 to 18; and wherein the charge recombination layer material has a refractive index, n(λ), at a wavelength, λ, of at least 2, wherein λ is a wavelength of from 500 nm to 1200 nm.

### BRIEF DESCRIPTION OF THE FIGURES

FIG. 1 shows a schematic diagram (top) and cross section SEM image (bottom) of a perovskite-perovskite tandem solar cell. (Figure taken from [Giles E. et al. Eperon, Science 354, no. 6314 (2016): 861-65].)

FIG. 2A shows how reflections from the recombination layer originate from the top cell, recombination layer interface (phase angle ϕ₁) and the recombination layer, bottom cell interface (phase angle ϕ₂). FIG. 2B shows the refractive indices of a 1.8 eV gap and a 1.2 eV band gap perovskite absorber layer, along with the refractive index of typical transparent conducting oxides, Fluorine doped Tin Oxide (FTO) and Indium Oxide Tin Oxide (ITO). Also shown is a dashed line which indicates an approximate ideal refractive index for minimizing the reflection losses between the two perovskite layers, calculated as \sqrt{n₁(λ₀)·n₂(λ₀)}, where n₁(λ₀) and n₂(λ₀) are the refractive index of the top and bottom perovskite layers at λ₀=850 nm.

FIG. 3A shows how external quantum efficiency (EQE) is affected by reflections constructively interfering (t_{ITO}=83 nm). FIG. 3B shows how EQE is affected by reflections destructively interfering (t_{ITO}=173 nm). FIG. 3C shows how EQE is affected when there is no recombination layer. FIG. 3D shows the variation in bottom cell current with recombination layer thickness.

FIG. 4A shows EQE results for an optimised Perovskite-Perovskite tandem with ITO recombination layer (203 nm) yielding a PCE of 28.8%. FIG. 4B shows EQE results for an optimised Perovskite-Perovskite tandem with n=2.45 interlayer, yielding a PCE of 29.38%. FIG. 4C shows current density in the bottom cell as a function of recombination layer thickness and refractive index. FIG. 4D shows PCE as a function of recombination layer thickness for ITO and a material of refractive index 2.2.

FIG. 5A shows PCE as a function of Nb:TiO₂ fraction in a ITO/Nb:TiO₂ blended interlayer. FIG. 5B shows PCE as a function of recombination layer thickness for various ITO/Nb:TiO₂ blend ratios.

FIG. 6 shows how Nb:TiO₂ index-matched cells are less sensitive to changes in incidence angle. At 50° incidence, Nb:TiO₂ interlayer offers a 1.1% (absolute) efficiency gain over ITO interlayer.

FIG. 7 shows the PCE distribution with 5% standard deviation in layer thicknesses during manufacturing for refractive-index matched cells (TiO₂ interlayer) and ITO interlayer cells.

FIG. 8 is a schematic illustration of a prospective device stack with the optical spacer layer included. In this device stack, the recombination layer is Nb doped TiO₂ (Nb:TiO₂).

FIG. 9 shows the optical constants of the sputtered Nb doped (4%) TiO2 thin film (80 nm) of Example 2, measured using ellipsometry.

FIG. 10 shows the transmittance and reflectance spectra of the Nb doped (4%) TiO2 thin film (80 nm) of Example 2 sputtered on glass.

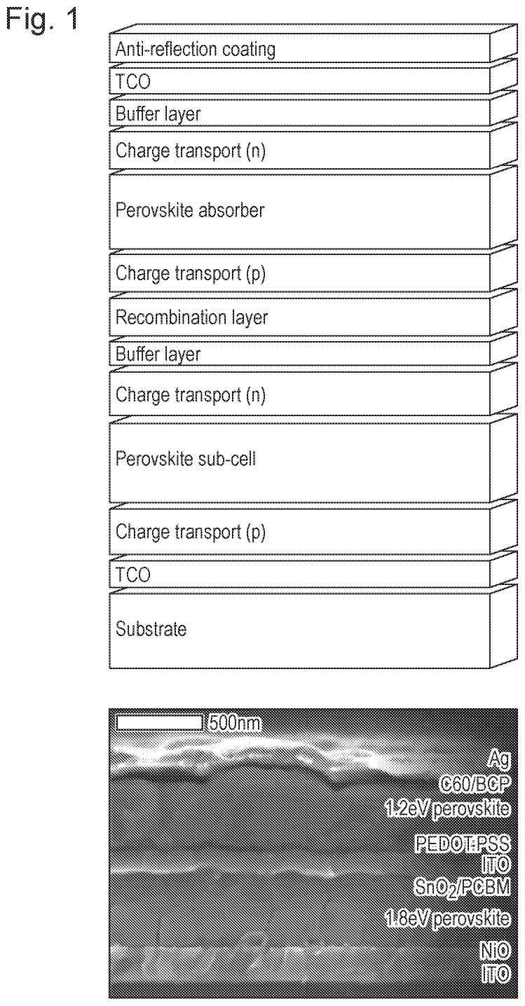

### DETAILED DESCRIPTION OF THE INVENTION

### Definitions

The term “crystalline” as used herein indicates a crystalline compound, which is a compound having an extended 3D crystal structure. A crystalline compound is typically in the form of crystals or, in the case of a polycrystalline compound, crystallites (i.e. a plurality of crystals having particle sizes of less than or equal to 1 m). The crystals together often form a layer. The crystals of a crystalline material may be of any size. Where the crystals have one or more dimensions in the range of from 1 nm up to 1000 nm, they may be described as nanocrystals.

The terms “organic compound” and “organic solvent” as used herein have their typical meaning in the art and would readily be understood by the skilled person.

The term “crystalline A/M/X material”, as used herein, refers to a material with a crystal structure which comprises one or more A ions, one or more M ions, and one or more X ions. A ions and M ions are cations. X ions are anions. A/M/X materials typically do not comprise any further types of ions.

The term “perovskite”, as used herein, refers to a material with a three-dimensional crystal structure related to that of CaTiO₃ or a material comprising a layer of material, which layer has a structure related to that of CaTiO₃. The structure of CaTiO₃ can be represented by the formula ABX₃, wherein A and B are cations of different sizes and X is an anion. In the unit cell, the A cations are at (0,0,0), the B cations are at (½, ½, ½) and the X anions are at (½, ½, 0). The A cation is usually larger than the B cation. The skilled person will appreciate that when A, B and X are varied, the different ion sizes may cause the structure of the perovskite material to distort away from the structure adopted by CaTiO₃ to a lower-symmetry distorted structure. The symmetry will also be lower if the material comprises a layer that has a structure related to that of CaTiO₃. Materials comprising a layer of perovskite material are well known. For instance, the structure of materials adopting the K₂NiF₄-type structure comprises a layer of perovskite material. The skilled person will appreciate that a perovskite material can be represented by the formula [A][B][X]₃, wherein [A] is at least one cation, [B] is at least one cation and [X] is at least one anion. When the perovskite comprise more than one A cation, the different A cations may distributed over the A sites in an ordered or disordered way. When the perovskite comprises more than one B cation, the different B cations may distributed over the B sites in an ordered or disordered way. When the perovskite comprise more than one X anion, the different X anions may distributed over the X sites in an ordered or disordered way. The symmetry of a perovskite comprising more than one A cation, more than one B cation or more than one X cation, will be lower than that of CaTiO₃. For layered perovskites the stoichiometry can change between the A, B and X ions. As an example, the [A]₂[B][X]₄ structure can be adopted if the A cation has a too large an ionic radii to fit within the 3D perovskite structure. The term “perovskite” also includes A/M/X materials adopting a Ruddleson-Popper phase. Ruddleson-Popper phase refers to a perovskite with a mixture of layered and 3D components. Such perovskites can adopt the crystal structure, Aₙ₋₁A′₂MₙX₃ₙ₊₁, where A and A′ are different cations and n is an integer from 1 to 8, or from 2 to 6. The term “mixed 2D and 3D” perovskite is used to refer to a perovskite film within which there exists both regions, or domains, of AMX₃ and Aₙ₋₁A′₂MₙX₃ₙ₊₁ perovskite phases.

The term “metal halide perovskite”, as used herein, refers to a perovskite, the formula of which contains at least one metal cation and at least one halide anion.

The term “mixed halide perovskite” as used herein refers to a perovskite or mixed perovskite which contains at least two types of halide anion.

The term “mixed cation perovskite” as used herein refers to a perovskite of mixed perovskite which contains at least two types of A cation.

The term “organic-inorganic metal halide perovskite”, as used herein, refers to a metal halide perovskite, the formula of which contains at least one organic cation.

The term “monocation”, as used herein, refers to any cation with a single positive charge, i.e. a cation of formula A⁺ where A is any moiety, for instance a metal atom or an organic moiety. The term “dication”, as used herein, refers to any cation with a double positive charge, i.e. a cation of formula A²⁺ where A is any moiety, for instance a metal atom or an organic moiety. The term “trication”, as used herein, refers to any cation with a triple positive charge, i.e. a cation of formula A³⁺ where A is any moiety, for instance a metal atom or an organic moiety. The term “tetracation”, as used herein, refers to any cation with a quadruple positive charge, i.e. a cation of formula A⁴⁺ where A is any moiety, for instance a metal atom.

The term “alkyl”, as used herein, refers to a linear or branched chain saturated hydrocarbon radical. An alkyl group may be a C₁₋₂₀ alkyl group, a C₁₋₁₄ alkyl group, a C₁₋₁₀ alkyl group, a C₁₋₆ alkyl group or a C₁₋₄ alkyl group. Examples of a C₁₋₁₀ alkyl group are methyl, ethyl, propyl, butyl, pentyl, hexyl, heptyl, octyl, nonyl or decyl. Examples of C₁₋₆ alkyl groups are methyl, ethyl, propyl, butyl, pentyl or hexyl. Examples of C₁₋₄ alkyl groups are methyl, ethyl, i-propyl, n-propyl, t-butyl, s-butyl or n-butyl. If the term “alkyl” is used without a prefix specifying the number of carbons anywhere herein, it has from 1 to 6 carbons (and this also applies to any other organic group referred to herein).

The term “cycloalkyl”, as used herein, refers to a saturated or partially unsaturated cyclic hydrocarbon radical. A cycloalkyl group may be a C₃₋₁₀ cycloalkyl group, a C₃₋₈ cycloalkyl group or a C₃₋₆ cycloalkyl group. Examples of a C₃₋₈ cycloalkyl group include cyclopropyl, cyclobutyl, cyclopentyl, cyclohexyl, cyclohexenyl, cyclohex-1,3-dienyl, cycloheptyl and cyclooctyl. Examples of a C₃₋₆ cycloalkyl group include cyclopropyl, cyclobutyl, cyclopentyl, and cyclohexyl.

The term “alkenyl”, as used herein, refers to a linear or branched chain hydrocarbon radical comprising one or more double bonds. An alkenyl group may be a C₂₋₂₀ alkenyl group, a C₂₋₁₄ alkenyl group, a C₂₋₁₀ alkenyl group, a C₂₋₆ alkenyl group or a C₂₋₄ alkenyl group. Examples of a C₂₋₁₀ alkenyl group are ethenyl (vinyl), propenyl, butenyl, pentenyl, hexenyl, heptenyl, octenyl, nonenyl or decenyl. Examples of C₂₋₆ alkenyl groups are ethenyl, propenyl, butenyl, pentenyl or hexenyl. Examples of C₂₋₄ alkenyl groups are ethenyl, i-propenyl, n-propenyl, s-butenyl or n-butenyl. Alkenyl groups typically comprise one or two double bonds.

The term “aryl”, as used herein, refers to a monocyclic, bicyclic or polycyclic aromatic ring which contains from 6 to 14 carbon atoms, typically from 6 to 10 carbon atoms, in the ring portion. Examples include phenyl, naphthyl, indenyl, indanyl, anthrecenyl and pyrenyl groups. The term “aryl group”, as used herein, includes heteroaryl groups.

The term “heteroaryl”, as used herein, refers to monocyclic or bicyclic heteroaromatic rings which typically contains from six to ten atoms in the ring portion including one or more heteroatoms. A heteroaryl group is generally a 5- or 6-membered ring, containing at least one heteroatom selected from O, S, N, P, Se and Si. It may contain, for example, one, two or three heteroatoms. Examples of heteroaryl groups include pyridyl, pyrazinyl, pyrimidinyl, pyridazinyl, furanyl, thienyl, pyrazolidinyl, pyrrolyl, oxazolyl, oxadiazolyl, isoxazolyl, thiadiazolyl, thiazolyl, isothiazolyl, imidazolyl, pyrazolyl, quinolyl and isoquinolyl.

The term “substituted”, as used herein in the context of substituted organic groups, refers to an organic group which bears one or more substituents selected from C₁₋₁₀ alkyl, aryl (as defined herein), cyano, amino, nitro, C₁₋₁₀ alkylamino, di(C₁₋₁₀)alkylamino, arylamino, diarylamino, aryl(C₁₋₁₀)alkylamino, amido, acylamido, hydroxy, oxo, halo, carboxy, ester, acyl, acyloxy, C₁₋₁₀ alkoxy, aryloxy, halo(C₁₋₁₀)alkyl, sulfonic acid, thiol, C₁₋₁₀ alkylthio, arylthio, sulfonyl, phosphoric acid, phosphate ester, phosphonic acid and phosphonate ester. Examples of substituted alkyl groups include haloalkyl, perhaloalkyl, hydroxyalkyl, aminoalkyl, alkoxyalkyl and alkaryl groups. When a group is substituted, it may bear 1, 2 or 3 substituents. For instance, a substituted group may have 1 or 2 substitutents.

The term “halide” as used herein indicates the singly charged anion of an element in group VIII of the periodic table. “Halide” includes fluoride, chloride, bromide and iodide.

The term “halo” as used herein indicates a halogen atom. Exemplary halo species include fluoro, chloro, bromo and iodo species.

As used herein, an amino group is a radical of formula —NR₂, wherein each R is a substituent. R is usually selected from hydrogen, alkyl, alkenyl, cycloalkyl, or aryl, wherein each of alkyl, alkenyl, cycloalkyl and aryl are as defined herein. Typically, each R is selected from hydrogen, C₁₋₁₀ alkyl, C₂₋₁₀ alkenyl, and C₃₋₁₀ cycloalkyl. Preferably, each R is selected from hydrogen, C₁₋₆ alkyl, C₂₋₆ alkenyl, and C₃₋₆ cycloalkyl. More preferably, each R is selected from hydrogen and C₁₋₆ alkyl.

A typical amino group is an alkylamino group, which is a radical of formula —NR₂ wherein at least one R is an alkyl group as defined herein. A C₁₋₆ alkylamino group is an alkylamino group wherein at least one R is an C₁₋₆ alkyl group.

As used herein, an imino group is a radical of formula R₂C═N— or —C(R)═NR, wherein each R is a substituent. That is, an imino group is a radical comprising a C═N moiety, having the radical moiety either at the N atom or attached to the C atom of said C═N bond. R is as defined herein: that is, R is usually selected from hydrogen, alkyl, alkenyl, cycloalkyl, or aryl, wherein each of alkyl, alkenyl, cycloalkyl and aryl are as defined herein. Typically, each R is selected from hydrogen, C₁₋₁₀ alkyl, C₂₋₁₀ alkenyl, and C₃₋₁₀ cycloalkyl. Preferably, each R is selected from hydrogen, C₁₋₆ alkyl, C₂₋₆ alkenyl, and C₃₋₆ cycloalkyl. More preferably, each R is selected from hydrogen and C₁₋₆ alkyl.

A typical imino group is an alkylimino group, which is a radical of formula R₂C═N— or —C(R)═NR wherein at least one R is an alkyl group as defined herein. A C₁₋₆ alkylimino group is an alkylimino group wherein the R substituents comprise from 1 to 6 carbon atoms. The term “ester” as used herein indicates an organic compound of the formula alkyl-C(═O)—O-alkyl, wherein the alkyl radicals are the same or different and are as defined herein. The alkyl radicals may be optionally substituted.

As used herein, the term “ammonium” indicates an organic cation comprising a quaternary nitrogen. An ammonium cation is a cation of formula R¹R²R³R⁴N⁺. R¹, R², R³, and R⁴ are substituents. Each of R¹, R², R³, and R⁴ are typically independently selected from hydrogen, or from optionally substituted alkyl, alkenyl, aryl, cycloalkyl, cycloalkenyl and amino; the optional substituent is preferably an amino or imino substituent. Usually, each of R¹, R², R³, and R⁴ are independently selected from hydrogen, and optionally substituted C₁₋₁₀ alkyl, C₂₋₁₀ alkenyl, C₃₋₁₀ cycloalkyl, C₃₋₁₀ cycloalkenyl, C₆₋₁₂ aryl and C₁₋₆ amino; where present, the optional substituent is preferably an amino group; particularly preferably C₁₋₆ amino. Preferably, each of R¹, R², R³, and R⁴ are independently selected from hydrogen, and unsubstituted C₁₋₁₀ alkyl, C₂₋₁₀ alkenyl, C₃₋₁₀ cycloalkyl, C₃₋₁₀ cycloalkenyl, C₆₋₁₂ aryl and C₁₋₆ amino. In a particularly preferred embodiment, R¹, R², R³, and R⁴ are independently selected from hydrogen, C₁₋₁₀ alkyl, and C₂₋₁₀ alkenyl and C₁₋₆ amino. Further preferably, R¹, R², R³, and R⁴ are independently selected from hydrogen, C₁₋₆ alkyl, C₂₋₆ alkenyl and C₁₋₆ amino.

As used herein, the term “iminium” indicates an organic cation of formula (R¹R²C═NR³R⁴)⁺, wherein R¹, R², R³, and R⁴ are as defined in relation to the ammonium cation. Thus, in a particularly preferred embodiment, of the iminium cation, R¹, R², R³, and R⁴ are independently selected from hydrogen, C₁₋₁₀ alkyl, C₂₋₁₀ alkenyl and C₁₋₆ amino. In a further preferable embodiment of the iminium cation, R¹, R², R³, and R⁴ are independently selected from hydrogen, C₁₋₆ alkyl, C₂₋₆ alkenyl and C₁₋₆ amino. Often, the iminium cation is formamidinium, i.e. R¹ is NH₂ and R², R³ and R⁴ are all H.

The term “optoelectronic device”, as used herein, refers to devices which source, control or detect light. Light is understood to include any electromagnetic radiation. Examples of optoelectronic devices include photovoltaic devices, photodiodes (including solar cells), phototransistors, photomultipliers, photoresistors, and light emitting diodes.

The term “consisting essentially of” refers to a composition comprising the components of which it consists essentially as well as other components, provided that the other components do not materially affect the essential characteristics of the composition. Typically, a composition consisting essentially of certain components will comprise greater than or equal to 95 wt % of those components or greater than or equal to 99 wt % of those components.

The terms “disposing on” or “disposed on”, as used herein, refers to the making available or placing of one component on another component. The first component may be made available or placed directly on the second component, or there may be a third component which intervenes between the first and second component. For instance, if a first layer is disposed on a second layer, this includes the case where there is an intervening third layer between the first and second layers. Typically, “disposing on” refers to the direct placement of one component on another.

The term “layer”, as used herein, refers to any structure which is substantially laminar in form (for instance extending substantially in two perpendicular directions, but limited in its extension in the third perpendicular direction). A layer may have a thickness which varies over the extent of the layer. Typically, a layer has approximately constant thickness. The “thickness” of a layer, as used herein, refers to the average thickness of a layer. The thickness of layers may easily be measured, for instance by using microscopy, such as electron microscopy of a cross section of a film, or by surface profilometry for instance using a stylus profilometer.

The term “band gap”, as used herein, refers to the energy difference between the top of the valence band and the bottom of the conduction band in a material. The skilled person of course is readily able to measure the band gap of a semiconductor (including that of a perovskite) by using well-known procedures which do not require undue experimentation. For instance, the band gap of a semiconductor can be estimated by constructing a photovoltaic diode or solar cell from the semiconductor and determining the photovoltaic action spectrum. Alternatively the band gap can be estimated by measuring the light absorption spectra either via transmission spectrophotometry or by photo thermal deflection spectroscopy. The band gap can be determined by making a Tauc plot, as described in Tauc, J., Grigorovici, R. & Vancu, a. Optical Properties and Electronic Structure of Amorphous Germanium. Phys. Status Solidi 15, 627-637 (1966) where the square of the product of absorption coefficient times photon energy is plotted on the Y-axis against photon energy on the x-axis with the straight line intercept of the absorption edge with the x-axis giving the optical band gap of the semiconductor. Alternatively, the optical band gap may be estimated by taking the onset of the incident photon-to-electron conversion efficiency, as described in [Barkhouse D A R, Gunawan O, Gokmen T, Todorov T K, Mitzi D B. Device characteristics of a 10.1% hydrazineprocessed Cu2ZnSn(Se,S)4 solar cell. Progress in Photovoltaics: Research and Applications 2012; published online DOI: 10.1002/pip.1160.]

The term “semiconductor” or “semiconducting material”, as used herein, refers to a material with electrical conductivity intermediate in magnitude between that of a conductor and a dielectric. A semiconductor may be a negative (n)-type semiconductor, a positive (p)-type semiconductor or an intrinsic (i) semiconductor. A semiconductor may have a band gap of from 0.5 to 3.5 eV, for instance from 0.5 to 2.5 eV or from 1.0 to 2.0 eV (when measured at 300 K).

The term “n-type region”, as used herein, refers to a region of one or more electron-transporting (i.e. n-type) materials. Similarly, the terms “n-type layer” refers to a layer of an electron-transporting (i.e. an n-type) material. An electron-transporting (i.e. an n-type) material could be a single electron-transporting compound or elemental material, or a mixture of two or more electron-transporting compounds or elemental materials. An electron-transporting compound or elemental material may be undoped or doped with one or more dopant elements.

The term “p-type region”, as used herein, refers to a region of one or more hole-transporting (i.e. p-type) materials. Similarly, the term “p-type layer” refers to a layer of a hole-transporting (i.e. a p-type) material. A hole-transporting (i.e. a p-type) material could be a single hole-transporting compound or elemental material, or a mixture of two or more hole-transporting compounds or elemental materials. A hole-transporting compound or elemental material may be undoped or doped with one or more dopant elements.

The term “electrode material”, as used herein, refers to any material suitable for use in an electrode. An electrode material will have a high electrical conductivity. The term “electrode” as used herein indicates a region or layer consisting of, or consisting essentially of, an electrode material.

The terms “chalcogenide” or “chalcogenide anion”, as used herein, refers to an anion of oxygen (O²⁻), sulfur (S²⁻), selenium (Se²⁻) or tellurium (Te²⁻).

The term “transition metal” as used herein means any one of the three series of elements arising from the filling of the 3d, 4d and 5d shells, and situated in the periodic table following the alkaline earth metals. This definition is used in N. N. Greenwood and A. Earnshaw “Chemistry of the Elements”, First Edition 1984, Pergamon Press Ltd., at page 1060, first paragraph, with respect to the term “transition element”. The same definition is used herein for the term “transition metal”. Thus, the term “transition metal”, as used herein, includes all of Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd and Hg. These are also referred to as the first, second and third row transition metals (i.e. the transition metals in periods 4, 5 and 6 of the periodic table).

The term “p-block metal” as used herein means any metal in the p-block of the periodic table. Thus, the term “p-block metal”, as used herein, refers to a metal selected from Al, Ga, Ge, In, Tl, Sn, Sb, Tl, Pb and Bi.

Multi-Junction Device

The present invention provides a multi-junction device comprising

a) a first photoactive region comprising a layer of a first photoactive material,

b) a second photoactive region comprising a layer of a second photoactive material, and

c) a charge recombination layer disposed between the first and second photoactive regions, wherein the charge recombination layer comprises a charge recombination layer material, wherein one of the first and second photoactive materials comprises at least one A/M/X material; wherein the other of the first and second photoactive materials comprises at least one A/M/X material or a compound which is a photoactive semiconductor other than an A/M/X material; wherein each A/M/X material is a crystalline compound of formula (I)

[A]ₐ[M]_{b}[X]_{c} (I)

wherein: [A] comprises one or more A cations; [M] comprises one or more M cations which are metal or metalloid cations; [X] comprises one or more X anions; a is a number from 1 to 6; b is a number from 1 to 6; and c is a number from 1 to 18; and wherein the charge recombination layer material has a refractive index, n(λ), at a wavelength, λ, of at least 2, wherein λ is a wavelength of from 500 nm to 1200 nm.

Thus, the refractive index, n(λ), of the charge recombination layer material may be at least two (2) at a single wavelength, λ, where λ is a wavelength of from 500 nm to 1200 nm. In other words, the requirement is satisfied if n(λ) is at least 2 at at least one wavelength, λ, in the range 500 nm to 1200 nm (which range includes both end points, 500 nm and 1200 nm).

In practice, the refractive index, n(λ), of the charge recombination layer material will often be at least two (2) at more than one wavelength in the range 500 nm to 1200 nm. It may for instance be at least 2 at a range of wavelengths in the range of from 500 nm to 1200 nm.

In some embodiments, the refractive index, n(λ), of the charge recombination layer material may be at least two (2) at all wavelengths in the range of from 500 nm to 1200 nm.

Typically, the charge recombination layer material has a low absorption co-efficient, α. For instance, typically α<10³ cm⁻¹ at wavelengths of between 650-1100 nm. Typically, the charge recombination layer material has a low resistivity, for instance a resistivity below 10⁵ Ωcm, below 10⁴ Ωcm, below 10³ Ωcm, below 500 Ωcm, below 250 Ωcm, below 100 Ωcm, below 50 Ωcm, below 10 Ωcm, below 5 Ωcm or below 1 Ωcm. In one embodiment, the charge recombination layer material has a resistivity in the range of 10⁵ Ωcm to 0.1 Ωcm, or in the range of 10⁵ Ωcm to 1 Ωcm, more preferably from 10³ Ωcm to 10 Ωcm.

Due to the risk of short circuiting the device via undesired contact of the top electrode with the recombination layer, it is advantageous if the recombination layer has an intermediate resistivity. Ideally, the resistivity should be low enough to enable low voltage loss recombination of carriers from the top and bottom sub cells, but high enough so as not to short-circuit a large portion of the device if the top contact makes physical contact with the recombination layer. In a thin film photovoltaic module, this occurrence may happen at the interconnection between different strings in the module, where through scribing and interconnection, it is necessary for the top electrode of one string to make physical and electronic contact to the bottom electrode of the neighbouring string, as described by Walter et al. [Walter et al. Closing the Cell-to-Module Efficiency Gap: A Fully Laser Scribed Perovskite Minimodule with 16% Steady-State Aperture Area Efficiency IEEE Journal of Photovoltaics, Vol 8, No. 1, January 2018]. A further problem to be solved therefore, before successful perovskite tandem modules can be made, is to find a chemically impermeable recombination layer which has an intermediate resistivity.

The charge recombination layer may comprise the charge recombination layer material having a refractive index, n(λ), at a wavelength, λ, of at least 2, wherein λ is a wavelength of from 500 nm to 1200 nm, and optionally one or more additional layers. Typically, the charge recombination layer consists essentially or consists of the charge recombination layer material having a refractive index, n(λ), at a wavelength, λ, of at least 2, wherein λ is a wavelength of from 500 nm to 1200 nm.

The charge recombination layer material typically has a refractive index, n(λ), at a wavelength, λ, of at least 2, wherein λ is a wavelength of from 500 nm to 1100 nm, of from 600 nm to 1200 nm, of from 550 nm to 1150 nm, from 600 nm to 1100 nm, from 600 and 1000 nm, or from 700 nm to 1000, or preferably from 800 nm to 1000 nm. For instance, the charge recombination layer material may have a refractive index, n(λ), at a wavelength, λ, of at least 2, wherein λ is a wavelength of about 500 nm, about 550 nm, about 600 nm, about 650 nm, about 700 nm, about 750 nm, about 800 nm, about 850 nm, about 900 nm, about 950 nm, about 1000 nm, about 1050 nm, about 1100 nm, about 1150 nm or about 1200 nm. Often, the charge recombination layer material has a refractive index, n(λ), at a wavelength, λ, of at least 2, wherein λ is a wavelength of from 800 nm to 900 nm. Typically, the charge recombination layer material has a refractive index, n(λ), at a wavelength, λ, of at least 2, wherein λ is a wavelength of 850 nm.

Typically, the refractive index n(λ) of the charge recombination layer material at the wavelength λ is less than 3.5, optionally less than or equal to 3, and more particularly less than or equal to 2.5, wherein λ is a wavelength of from 500 nm to 1200 nm. Typically, the charge recombination layer material may have a refractive index, n(λ), at a wavelength, λ, of at least 2 and less than 3, wherein λ is a wavelength of from 500 nm to 1200 nm, or of from 600 nm to 1200 nm, for instance from 550 nm to 1150 nm, from 600 nm to 1100 nm, from 700 nm to 1000 nm, or from 800 to 1000 nm, e.g. from 800 nm to 900 nm, for instance about 850 nm. For instance, the charge recombination layer material may have a refractive index, n(λ), at a wavelength, λ, of at least 2 and less than 2.75, wherein λ is a wavelength of from 500 nm to 1200 nm, or of from 600 nm to 1200 nm, for instance from 550 nm to 1150 nm, from 600 nm to 1100 nm, or from 700 nm to 1000 nm, or from 800 to 1000 nm, e.g. from 800 nm to 900 nm, for instance about 850 nm. Preferably, the charge recombination layer material may have a refractive index, n(λ), at a wavelength, λ, of at least 2 and less than 2.5, wherein λ is a wavelength of from 500 nm to 1200 nm, or of from 600 nm to 1200 nm, for instance from 550 nm to 1150 nm, from 600 nm to 1100 nm, or from 700 nm to 1000 nm, or from 800 to 1000 nm, e.g. from 800 nm to 900 nm, for instance about 850 nm.

Typically, the charge recombination layer material has a refractive index n(λ_{A}) at a wavelength λ_{A} and the first photoactive material has a refractive index n₁(λ_{A}) at the wavelength λ_{A}, wherein n₁(λ_{A}) is less than n(λ_{A}) and wherein λ_{A} is a wavelength of from 500 nm to 1200 nm which is the same as or different from λ. Thus, at the wavelength λ_{A}, n₁(λ_{A})<n(λ_{A}).

Typically, the first photoactive material has a refractive index n₁(λ_{A}) at the wavelength λ_{A}, of at least 1, at least 1.5 or at least 2. For instance, the first photoactive material may have a refractive index n₁(λ_{A}) at the wavelength λ_{A}, of between 1 and 3, typically between 1.5 and 2.5, for instance between 1.5 and 2.0 or between 2.0 and 2.5.

When the wavelength λ_{A} is the same as k, the charge recombination layer material has a refractive index n(λ_{A}) of at least two at the wavelength λ_{A}, and the first photoactive material has a refractive index n₁(λ_{A}) less than n(λ_{A}) at the wavelength λ_{A}, wherein both k and λ_{A} are a wavelength of from 500 nm to 1200 nm, of from 600 nm to 1200 nm, for instance from 550 nm to 1150 nm, from 600 nm to 1100 nm, from 700 nm to 1000 nm, or from 800 nm to 1000 nm, e.g. from 800 nm to 900 nm. Thus, in this embodiment, n(λ_{A})>2 and n(λ_{A})>n₁(λ_{A}).

The wavelength λ_{A} may be different from λ. Thus, at one wavelength, λ, the refractive index n(λ) of the charge recombination layer material is at least 2, and at another wavelength, λ_{A}, the charge recombination layer material has a refractive index n(λ_{A}) at a wavelength λ_{A} and the first photoactive material has a refractive index n₁(λ_{A}) at the wavelength λ_{A}, wherein n₁(λ_{A}) is less than n(λ_{A}), wherein both k and λ_{A} are (different) wavelengths of from 500 nm to 1200 nm, of from 600 nm to 1200 nm, for instance from 550 nm to 1150 nm, from 600 nm to 1100 nm, from 700 nm to 1000 nm, or from 800 nm to 1000 nm, e.g. from 800 nm to 900 nm.

The charge recombination layer material may have a refractive index n(λ_{A}) at a wavelength λ_{A} and the second photoactive material has a refractive index n₂(λ_{A}) at the wavelength λ_{A}, wherein n₂(λ_{A}) is greater than n(λ_{A}) and wherein λ_{A} is a wavelength of from 500 nm to 1200 nm which is the same as or different from λ. Thus, at the wavelength λ_{A}, n₂(λ_{A})>n(λ_{A}).

Typically, the second photoactive material has a refractive index n₂(λ_{A}) at the wavelength A, of at least 1.5, or at least 2 or at least 2.5. For instance, the second photoactive material may have a refractive index n₂(λ_{A}) at the wavelength λ_{A}, of between 1.5 and 3.5, typically between 2 and 3, for instance between 2 and 2.5 or between 2.5 and 3.

When the wavelength λ_{A} is the same as λ, the charge recombination layer material has a refractive index n(λ_{A}) of at least two at the wavelength λ_{A}, and the second photoactive material has a refractive index n₂(λ_{A}) greater than n(λ_{A}) at the wavelength λ_{A}, wherein both λ and λ_{A} are a (the same) wavelength of from 500 nm to 1200 nm, of from 600 nm to 1200 nm, for instance from 550 nm to 1150 nm, from 600 nm to 1100 nm, from 700 nm to 1000 nm, or from 800 nm to 1000 nm. Thus, in this embodiment, n(λ_{A})>2 and n(λ_{A})<n₂(λ_{A}).

The wavelength λ_{A} may be different from λ. Thus, at one wavelength, λ, the refractive index n(λ) of the charge recombination layer material is at least 2, and at another wavelength, λ_{A}, the charge recombination layer material has a refractive index n(λ_{A}) at a wavelength λ_{A} and the second photoactive material has a refractive index n₂(λ_{A}) at the wavelength λ_{A}, wherein n₂(λ_{A}) is greater than n(λ_{A}), wherein both k and λ_{A} are (different) wavelengths of from 500 nm to 1200 nm, of from 600 nm to 1200 nm, for instance from 550 nm to 1150 nm, from 600 nm to 1100 nm, from 700 nm to 1000 nm, or from 800 nm to 1000 nm.

Thus, typically, the charge recombination layer material has a refractive index n(λ_{A}) at a wavelength λ_{A}, the first photoactive material has a refractive index n₁(λ_{A}) at the wavelength λ_{A} and the second photoactive material has a refractive index n₂(λ_{A}) at the wavelength λ_{A}, wherein n₁(λ_{A}) is less than n(λ_{A}), and n₂(λ_{A}) is greater than n(λ_{A}), and wherein λ_{A} is a wavelength of from 500 nm to 1200 nm which is the same as or different from λ. Thus, at the wavelength λ_{A}, n₂(λ_{A})>n(λ_{A})>n₁(λ_{A}).

In embodiments discussed above, typically λ_{A} is from 500 nm to 1200 nm, from 600 nm to 1200 nm, from 500 and 1100 nm, of from 550 nm to 1150 nm, from 600 nm to 1100 nm, from 600 and 1000 nm, or from 700 nm to 1000, or from 800 nm to 1000 nm, e.g. 800 nm to 900 nm. λ_{A} may be about 500 nm, about 550 nm, about 600 nm, about 650 nm, about 700 nm, about 750 nm, about 800 nm, about 850 nm, about 900 nm, about 950 nm, about 1000 nm, about 1050 nm, about 1100 nm, about 1150 nm or about 1200 nm. Typically, λ_{A} is about 850 nm.

In embodiments discussed above, typically λ_{A} and λ are the same wavelength. For instance, both λ_{A} and λ may be the same wavelength, wherein said wavelength is from 500 nm to 1200 nm, from 600 nm to 1200 nm, from 500 and 1100 nm, of from 550 nm to 1150 nm, from 600 nm to 1100 nm, from 600 and 1000 nm, or from 700 nm to 1000, or from 800 nm to 1000 nm, e.g. from 800 nm to 900 nm. Both λ_{A} and λ may be about 500 nm, about 550 nm, about 600 nm, about 650 nm, about 700 nm, about 750 nm, about 800 nm, about 850 nm, about 900 nm, about 950 nm, about 1000 nm, about 1050 nm, about 1100 nm, about 1150 nm or about 1200 nm. Typically, λ_{A} and λ are both about 850 nm.

The charge recombination layer material is usually a semi-transparent material. Typically the charge recombination layer material has a mean optical transparency in the visible to near infrared range of the spectrum which is equal to or greater than about 50%, for instance equal to or greater than about 60%, equal to or greater than about 70%, equal to or greater than about 80% or equal to or greater than about 90%. It may for instance have a mean optical transparency in the visible range of the spectrum which is from 50% to 90%, for instance from 60% to 85%, for instance from 70% to 80%, or for example from 80% to 95% for example from 90% to 95%. The visible range of the spectrum is generally understood to be from about 400 nm to about 700 nm. Preferably, the charge recombination layer material is semi-transparent to wavelengths in the range of from 700 to 1100 nm. For instance, the charge recombination layer material has a mean optical transparency in the range of the spectrum from 700 nm to 1100 nm which is equal to or greater than about 50%, for instance equal to or greater than about 60%, equal to or greater than about 70%, equal to or greater than about 80% or equal to or greater than about 90%. It may for instance have a mean optical transparency in the range of the spectrum from 700 nm to 1100 nm which is from 50% to 90%, for instance from 60% to 85%, for instance from 70% to 80%, or for example from 80% to 95% for example from 90% to 95%.

Typically, the charge recombination layer material has a band gap of at least 2 eV, at least 2.5 eV or at least 3 eV, for instance at least 3.2 eV, or at least 3.5 eV. Thus, typically, the charge recombination layer material is a wide band-gap semiconductor.

Typically, the first photoactive material has a band gap Eg₁ the second photoactive material has a band gap Eg₂, wherein Eg₁ is greater than Eg₂ (Eg₁>Eg₂). Typically, both Eg₁ and Eg₂ are less than or equal to 3 eV, for instance less than or equal to 2.8 eV, less than or equal to 2.5 eV, less than or equal to 2.3 eV or less than or equal to 2.0 eV.

Typically, the first photoactive material has a band gap Eg₁ and the charge recombination layer material has a band gap Eg, wherein Eg is greater than Eg₁. Thus, typically, Eg>Eg₁.

Typically, the charge recombination layer material has a band gap Eg, the first photoactive material has a band gap Eg₁, and the second photoactive material has a band gap Eg₂, wherein Eg is greater than Eg₁ and Eg₁ is greater than Eg₂. Thus, typically Eg>Eg₁>Eg₂. Usually, Eg is at least 2.0 eV, for instance Eg may be at least 3.0 eV and Eg₁ may be 3.0 eV or less, 2.8 eV or less, 2.5 eV or less, 2.3 eV or less or 2.0 eV or less. Eg may for instance be at least 3.2 eV, or at least 3.5 eV.

Typically, the charge recombination layer has a thickness of at least 5 nm, for instance a thickness of from 20 to 300 nm, or from 20 to 200 nm, more particularly a thickness of from 50 to 200 nm, or a thickness of from 75 to 150 nm or from 80 to 125 nm, or from 90 to 110 nm. For instance, the charge recombination layer may have a thickness of about 100 nm.

The charge recombination layer may have a thickness in nm of λo/4n±50%, wherein λₒ is a wavelength of from 500 nm to 1200 nm which is the same as or different from λ, and n is the refractive index of the charge recombination layer material at λₒ.

For instance, the charge recombination layer may have a thickness in nm of

$$\frac{λ o}{4 n} \pm 25 \% , or \frac{λ o}{4 n} \pm 10 \% ,$$

wherein λₒ is a wavelength of from 500 nm to 1200 nm which is the same as or different from λ, and n is the refractive index of the charge recombination layer material at λₒ.

There are also other thickness of the charge recombination layer which will result in minima in reflection losses. In one embodiment, the charge recombination layer may have a thickness in nm of

$$\frac{3 λ o}{4 n} \pm 25 \% , or \frac{3 λ o}{4 n} \pm 10 \% ,$$

wherein λₒ is a wavelength of from 500 nm to 1200 nm which is the same as or different from λ, and n is the refractive index of the charge recombination layer material at λₒ.

In another embodiment, the charge recombination layer may have a thickness in nm of

$$\frac{5 λ o}{4 n} \pm 25 \% , or \frac{5 λ o}{4 n} \pm 10 \% ,$$

wherein λₒ is a wavelength of from 500 nm to 1200 nm which is the same as or different from λ, and n is the refractive index of the charge recombination layer material at λₒ.

In embodiments discussed above, typically λₒ is from 500 nm to 1200 nm, from 600 nm to 1200 nm, from 500 and 1100 nm, of from 550 nm to 1150 nm, from 600 nm to 1100 nm, from 600 and 1000 nm, or from 700 nm to 1000, or from 800 nm to 1000 nm, e.g. from 800 nm to 900 nm. λₒ may be about 500 nm, about 550 nm, about 600 nm, about 650 nm, about 700 nm, about 750 nm, about 800 nm, about 850 nm, about 900 nm, about 950 nm, about 1000 nm, about 1050 nm, about 1100 nm, about 1150 nm or about 1200 nm. Typically, λₒ is about 850 nm.

Typically, λₒ is the same as λ. For instance, both λₒ and λ may be the same wavelength, wherein said wavelength is from 500 nm to 1200 nm, from 600 nm to 1200 nm, for instance from 550 nm to 1150 nm, from 600 nm to 1100 nm, or from 700 nm to 1000 nm, e.g. from 800 nm to 900 nm. Both λ₀ and λ may be about 500 nm, about 550 nm, about 600 nm, about 650 nm, about 700 nm, about 750 nm, about 800 nm, about 850 nm, about 900 nm, about 950 nm, about 1000 nm, about 1050 nm, about 1100 nm, about 1150 nm or about 1200 nm.

Typically, one of the first and second photoactive materials comprises at least one A/M/X material as described herein and the other of the first and second photoactive materials comprises a compound which is a photoactive semiconductor other than an A/M/X material. For instance, one of the first and second photoactive materials may consist essentially of, or consist of at least one A/M/X material as described herein and the other of the first and second photoactive materials may consist essentially of, or consist of a compound which is a photoactive semiconductor other than an A/M/X material.

Typically, the first photoactive material comprises at least one crystalline A/M/X material as described herein, and the second photoactive material comprises a compound which is a photoactive semiconductor other than an A/M/X material. For instance, the first photoactive material may consist essentially of, or consist of at least one crystalline A/M/X material as described herein, and the second photoactive material may consist essentially of, or consist of a compound which is a photoactive semiconductor other than an A/M/X material.

Alternatively, the first photoactive material may comprise a compound which is a photoactive semiconductor other than an A/M/X material and the second photoactive material may comprises at least one A/M/X material as described herein. For instance, the first photoactive material may consist essentially of, or consist of a compound which is a photoactive semiconductor other than an A/M/X material and the second photoactive material may consist essentially of, or consist of at least one A/M/X material as described herein.

In some embodiments, the multi-junction device may comprise a third photoactive region comprising a layer of a third photoactive material. The third photoactive material may be as described herein for the first and second photoactive materials. For instance, the third photoactive material may comprise, consist essentially of or consist of at least one A/M/X material as described herein. The third photoactive material may comprise, consist essentially of or consist of a material which is a photoactive semiconductor other than an A/M/X material. For example, the third photoactive material may comprise, consist essentially of or consist of a compound which is a photoactive semiconductor other than an A/M/X material, as described herein. Materials which are photoactive semiconductors other than an A/M/X material are known to the skilled person. Such materials include silicon-based materials, such as crystalline silicon (c-Si), and the compounds which are photoactive semiconductors other than an A/M/X material described herein.

In one embodiment, each of the first, second and third photoactive materials comprises at least one A/M/X material as described herein. Each of the first, second and third photoactive materials may comprise a different A/M/X material as described herein.

In one embodiment, each of the first and second photoactive materials comprise at least one A/M/X material as described herein, and the third photoactive material comprises a material which is a photoactive semiconductor other than an A/M/X material. For instance, each of the first and second photoactive materials comprise at least one A/M/X material as described herein, and the third photoactive material comprises a compound which is a photoactive semiconductor other than an A/M/X material, as described herein.

In one embodiment, one of the first and second photoactive materials comprises at least one A/M/X material as described herein, the other of the first and second photoactive materials comprises a compound which is a photoactive semiconductor other than an A/M/X material, and the third photoactive material comprises a material which is a photoactive semiconductor other than an A/M/X material, for instance a compound which is a photoactive semiconductor other than an A/M/X material, as described herein.

Typically, in the embodiments where a layer of a third photoactive material is present, the device comprises a second charge recombination layer. The second charge recombination layer may be as defined anywhere herein for the charge recombination layer. The second charge recombination layer may be the same as or different from the charge recombination layer. The second charge recombination layer may comprise a charge recombination layer material as defined herein. The second charge recombination layer may comprise the same charge recombination layer material as the charge recombination layer. Alternatively, the second charge recombination layer may comprise a different charge recombination layer material from that which the charge recombination layer comprises.

Material that is a Photoactive Semiconductor Other than an A/M/X Material

Photoactive semiconductors other than an A/M/X materials are known to the skilled person. Typically, the compound which is a photoactive semiconductor comprises a chalcogenide anion. Typically the compound which is a photoactive semiconductor is a metal chalcogenide, comprising at least one metal and at least one chalcogenide anion. The metal chalcogenide may comprise at least two different metals and at least one chalcogenide anion. The metal chalcogenide may comprise at least two different metals and at least two different chalcogenide anions.

Typically, the metal is selected from transition metals and p-block metals. For instance, the metal may be selected from gallium, niobium, tantalum, tungsten, indium, neodinium, palladium, copper, lead, antimony, zinc, iron, or bismuth.

Typically, the photoactive semiconductor compound is selected from copper zinc tin chalcogenides, antimony chalcogenides, bismuth chalcogenides, copper indium gallium chalcognides, cadmium chalcogenides, iron chalcogenides and lead chalcogenides. Further examples are group IV compound semiconductors; group III-V semiconductors (e.g. gallium arsenide); group II-VI semiconductors (e.g. cadmium selenide); group I-VII semiconductors (e.g. cuprous chloride); group IV-VI semiconductors (e.g. lead selenide); group V-VI semiconductors (e.g. bismuth telluride); and group II-V semiconductors (e.g. cadmium arsenide).

For instance, the photoactive semiconductor compound may be selected from copper indium gallium selenide (CIGS), copper indium sulphide (CIS), copper indium sulphide selenide (CIG(S)Se), cadmium telluride (CdTe), cadmium telluride selenide (CdTeₓSe₁₋ₓ where 0<x<1), cadmium telluride sulfide (CdTeₓS₁₋ₓ, where 0<x<1), copper zinc tin sulphide (CZTS), copper zinc tin selenide (CZTSe), copper zinc tin sulphide selenide (CZTSSe), antimony sulphide, antimony selenide, bismuth sulphide, bismuth selenide, iron sulphide, lead sulphide, lead selenide, cadmium sulphide, and cadmium selenide.

Preferably, the photoactive semiconductor compound is selected from copper indium gallium selenide (CIGS), copper indium sulphide (CIS), copper indium sulphide selenide (CIG(S)Se), cadmium telluride (CdTe), cadmium telluride selenide (CdTeₓSe₁₋ₓ, where 0<x<1), cadmium telluride sulfide (CdTeₓS₁₋ₓ, where 0<x<1), copper zinc tin sulphide (CZTS), copper zinc tin selenide (CZTSe) and copper zinc tin sulphide selenide (CZTSSe). For instance the photoactive semiconductor compound may be copper indium gallium selenide (CIGS), cadmium telluride (CdTe), cadmium telluride selenide (CdTeₓSe₁₋ₓ, where 0<x<1) or cadmium telluride sulfide (CdTeₓSiₓ, where 0<x<1).

Typically, the photoactive semiconductor has a band gap of less than 3.0 eV, for instance less than 2.5 eV or less than 2.0 eV. The photoactive semiconductor may have a band gap of at least 0.5 eV, at least 0.8 eV or at least 1.0 eV. Typically, the photoactive semiconductor has a band gap of between 1.0 eV and 2.0 eV, for instance between 1.0 eV and 1.5 eV, or between 1.5 eV and 2.0 eV.

When the first photoactive material comprises at least one crystalline A/M/X material as described herein, and the second photoactive material comprises a compound which is a photoactive semiconductor other than an A/M/X material, typically the first A/M/X material has a band gap Eg₁ and the second photoactive material has a band gap Eg₂, wherein Eg₁ is greater than Eg₂ (Eg₁>Eg₂). Typically, both Eg₁ and Eg₂ are less than or equal to 3.0 eV, for instance less than or equal to 2.5 eV or less than or equal to 2.0 eV.

For example, Eg₁ may be greater than or equal to 1.5 eV and Eg₂ may be less than or equal to 1.5 eV. Typically, Eg₁ is between 1.5 eV and 3 eV, for instance 1.5 eV and 2.5 eV or 1.5 eV and 2 eV. Typically, Eg₂ is between 0.5 eV and 1.5 eV, for instance 0.75 eV and 1.5 eV, between 0.75 eV and 1.25 eV, or 1 eV and 1.5 eV. Eg₁ may be about 1.5 eV, 1.6 eV, 1.7 eV, 1.8 eV, 1.9 eV or 2.0 eV. Eg₂ may be about 1 eV, 1.1 eV, 1.2 eV, 1.3 eV, 1.4 eV or 1.5 eV. For instance, Eg₁ may be between 1.5 eV and 2.0 eV and Eg₂ may be between 1 eV and 1.5 eV, for instance between 1 eV and 1.2 eV.

Typically, the first photoactive material comprising at least one crystalline A/M/X material has a band gap Eg₁ and the charge recombination layer material has a band gap Eg, wherein Eg is greater than Eg₁. Thus, typically, Eg>Eg₁.

Typically, the charge recombination layer material has a band gap Eg, the first photoactive material comprising at least one crystalline A/M/X material has a band gap Eg₁, and the second photoactive material comprising a compound which is a photoactive semiconductor other than an A/M/X material has a band gap Eg₂, wherein Eg is greater than Eg₁ and Eg₁ is greater than Eg₂. Thus, typically Eg>Eg₁>Eg₂. Usually, Eg is at least 2.0 eV, for instance Eg may be at least 3.0 eV and Eg₁ may be 2.0 eV or less.

First and Second Photoactive Materials are Both A/M/X Materials

Typically the first photoactive material comprises at least one first A/M/X material as described herein, and the second photoactive material comprises at least one second A/M/X material as described herein. Typically, the first photoactive material consists essentially of or consists of at least one first A/M/X material as described herein, and the second photoactive material consists essentially of or consists of at least one second A/M/X material as described herein. Preferably, the at least one first and second crystalline A/M/X materials are different.

Typically, the at least one first and second crystalline A/M/X materials have different band gaps. Typically, when the first photoactive material comprises at least one first A/M/X material as described herein, and the second photoactive material comprises at least one second A/M/X material as described herein, the first A/M/X material has a band gap Eg₁ and the second A/M/X material has a band gap Eg₂, wherein Eg₁ is greater than Eg₂ (Eg₁>Eg₂). Typically, both Eg₁ and Eg₂ are less than or equal to 3.0 eV, for instance less than or equal to 2.5 eV or less than or equal to 2.0 eV.

For example, Eg₁ may be greater than or equal to 1.5 eV and Eg₂ may be less than or equal to 1.5 eV. Typically, Eg₁ is between 1.5 eV and 3 eV, for instance 1.5 eV and 2.5 eV or 1.5 eV and 2 eV. Typically, Eg₂ is between 0.5 eV and 1.5 eV, for instance 0.75 eV and 1.5 eV or 1 eV and 1.5 eV. Eg₁ may be about 1.5 eV, 1.6 eV, 1.7 eV, 1.8 eV, 1.9 eV or 2.0 eV. Eg₂ may be about 1 eV, 1.1 eV, 1.2 eV, 1.3 eV, 1.4 eV or 1.5 eV. For instance, Eg₁ may be between 1.5 eV and 2.0 eV and Eg₂ may be between 1 eV and 1.5 eV.

Typically, the first A/M/X material has a band gap Eg₁ and the charge recombination layer material has a band gap Eg, wherein Eg is greater than Eg₁. Thus, typically, Eg>Eg₁.

Typically, the charge recombination layer material has a band gap Eg, the first A/M/X material has a band gap Eg₁, and the second A/M/X material has a band gap Eg₂, wherein Eg is greater than Eg₁ and Eg₁ is greater than Eg₂. Thus, typically Eg>Eg₁>Eg₂.

Usually, Eg is at least 2.0 eV, for instance Eg may be at least 3.0 eV and Eg₁ may be 2.0 eV or less.

Charge Recombination Layer Material

The charge recombination layer material may be an organic or an inorganic material. Preferably, the charge recombination layer material is an inorganic material. Generally, inorganic materials are less easily damaged by application of a solvent when constructing the layers above.

Typically, the charge recombination layer material comprises a metal oxide, a metal nitride or a metal sulfide, For example the charge recombination layer material may comprise TiO₂, metal doped-TiO₂, SrTiO₃, BaTiO₃, Cr₂O₃, CuCrO₂, ZnS, ZrO₂, AlN, GaN, and TiN, Preferably, the charge recombination layer material comprises TiO₂ or metal-doped TiO₂.

Typically, the charge recombination layer material comprises (a) TiO₂ or metal-doped TiO₂ and (b) a transparent conducting oxide. Preferably, the charge recombination layer material comprises a blend of (a) and (b). The transparent conducting oxide may be selected from fluorine doped tin oxide (FTO), aluminium doped zinc oxide (AZO) and indium doped tin oxide (ITO). Usually, the transparent conducting oxide is indium tin oxide (ITO).

Typically, when the charge recombination layer material comprises a blend of (a) and (b), the TiO₂ or metal-doped TiO₂ is at least 20% by volume of the total volume of the transparent conducting oxide and the TiO₂ or metal-doped TiO₂. For instance, the TiO₂ or metal-doped TiO₂ may be at least 30%, at least 40%, at least 50%, at least 60%, at least 70%, at least 80%, or at least 90% by volume of the total volume of the transparent conducting oxide and the TiO₂ or metal-doped TiO₂.

The charge recombination layer material typically comprises metal-doped TiO₂. The metal is usually a transition metal. Typically, the transition metal is selected from Ta, V and Nb. Preferably the transition metal is Nb.

The metal in the metal-doped TiO₂ may be present in an amount of at least 0.5% by weight of the total weight of the metal-doped TiO₂. For instance, the metal in the metal-doped TiO₂ may be present in an amount of at least 1% by weight of the total weight of the metal-doped TiO₂. Typically the metal in the metal-doped TiO₂ may be present in an amount of from 1 to 10% by weight of the total weight of the metal-doped TiO₂, or from 2 to 6% by weight of the total weight of the metal-doped TiO₂. Thus, in one embodiment, the metal in the metal-doped TiO2 is Ta, V or Nb, preferably Nb, in an amount of from 1 to 10%, for instance from 2 to 6% by weight of the total weight of the metal-doped TiO₂.

The charge recombination layer material may comprise a blend of a metal-doped TiO₂, wherein the metal is selected from Ta, V or Nb, preferably Nb, and a transparent conducting oxide. The metal-doped TiO₂, preferably Nb-doped TiO₂, is at least 20% by volume of the total volume of the transparent conducting oxide and the metal-doped TiO₂. For instance, the metal-doped TiO₂, preferably Nb-doped TiO₂, may be at least at least 30%, at least 40%, at least 50%, at least 60%, at least 70%, at least 80%, or at least 90% by volume of the total volume of the transparent conducting oxide and the metal-doped TiO₂.

The titanium dioxide may be in any amorphous or crystalline form. It may therefore be in, for example, anatase, rutile or brookite forms. Typically, in charge recombination layers that comprise TiO₂, the TiO₂ in is in the rutile phase.

Hence, in one embodiment, the charge recombination layer comprises TiO₂ in the rutile phase doped with a transition metal selected from Ta, V and Nb, preferably Nb, in an amount of from 1 to 10%, from 2 to 6%, for instance about 4% by weight of the total weight of the metal-doped TiO₂.

The charge recombination layer material may consists essentially of or consist of TiO₂ or metal-doped TiO₂. The charge recombination layer material may consists essentially of or consists of metal-doped TiO₂. The metal is usually a transition metal. Typically, the transition metal is selected from Ta, V and Nb. Typically the transition metal is Nb. Typically the metal, preferably Nb, is present in an amount of from 1 to 10%, from 2 to 6%, for instance about 4% by weight of the total weight of the metal-doped TiO₂. Thus, the charge recombination layer material may consist essentially of or consist of Nb doped TiO₂, wherein the Nb is present in an amount of from 1 to 10%, from 2 to 6%, for instance about 4% by weight of the total weight of the metal-doped TiO₂.

In one embodiment, the charge recombination layer comprises a layer of the charge recombination layer material and one or more additional layers. For instance, the charge recombination layer may comprise a layer of the charge recombination layer material and two additional layers. The additional layers may be layers of a transparent conducting oxide, for instance may be selected from fluorine doped tin oxide (FTO), aluminium doped zinc oxide (AZO) and indium doped tin oxide (ITO). Usually, the additional layers are layers of indium tin oxide (ITO). Hence, the charge recombination layer may comprise the following layers in the following order:
additional layer of a transparent conducting oxide, preferably ITO;
layer of the charge recombination layer material, as described herein;
additional layer of a transparent conducting oxide, preferably ITO.

Typically the additional layers each have a thickness of less than 100 nm, less than 50 nm, less than 25 nm, less than 10 nm, preferably about 5 nm. Typically, the charge recombination layer material is TiO₂ or metal-doped TiO₂ as described herein. The layer of the charge recombination layer may have any thickness as described herein. Typically the layer of the charge recombination layer material is from 20 to 300 nm, for instance from 20 to 200 nm.

Thus, the charge recombination layer may comprise, consist essentially or consist of the following layers in the following order:
additional layer of ITO;
layer of TiO₂ or metal-doped TiO₂, as described herein;
additional layer of ITO.

A/M/X Material

Thus, the multi-junction device of the present invention comprises at least one layer of a photoactive material comprising at least one crystalline A/M/X material, the crystalline A/M/X material comprising a compound of formula: [A]ₐ[M]_{b}[X]_{c}, wherein: [A] comprises one or more A cations; [M] comprises one or more M cations which are metal or metalloid cations; [X] comprises one or more X anions; a is a number from 1 to 6; b is a number from 1 to 6; and c is a number from 1 to 18. a is often a number from 1 to 4, b is often a number from 1 to 3, and c is often a number from 1 to 8.

Each of a, b and c may or may not be an integer. For instance, a, b or c may not be an integer where the compound adopts a structure having vacancies such that the crystal lattice is not completely filled. The method of the invention provides very good control over stoichiometry of the product and so is well-suited for forming structures where a, b or c is not an integer (for instance a structure having vacancies in one or more of the A, M or X sites). Accordingly, in some embodiments, one or more of a, b and c is a non-integer value. For example, one of a, b and c may be a non-integer value. In one embodiment, a is a non-integer value. In another embodiment, b is a non-integer value. In yet another embodiment, c is a non-integer value.

In other embodiments, each of a, b and c are integer values. Thus, in some embodiments, a is an integer from 1 to 6; b is an integer from 1 to 6; and c is an integer from 1 to 18. a is often an integer from 1 to 4, b is often an integer from 1 to 3, and c is often an integer from 1 to 8.

In the compound of formula [A]ₐ[M]_{b}[X]_{c}, generally: [A] comprises one or more A cations, which A cations may for instance be selected from alkali metal cations or organic monocations; [M] comprises one or more M cations which are metal or metalloid cations selected from Pd⁴⁺, W⁴⁺, Re⁴⁺, Os⁴⁺, Ir⁴⁺, Pt⁴⁺, Sn⁴⁺, Pb⁴⁺, Ge⁴⁺, Te⁴⁺, Bi³⁺, Sb³⁺, Ca²⁺, Sr²⁺, Cd²⁺, Cu²⁺, Ni²⁺, Mn²⁺, Fe²⁺, Co²⁺, Pd+, Ge²⁺, Sn²⁺, Pb²⁺, Yb²⁺ and Eu²⁺, preferably Sn²⁺, Pb²⁺, Cu²⁺, Ge²⁺, and Ni²⁺; particularly preferably Pb²⁺ and Sn²⁺; [X] comprises one or more X anions selected from halide anions (e.g. Cl⁻, Br⁻, and I⁻), O²⁻, S²⁻, Se²⁻, and Te²⁻; a is a number from 1 to 4; b is a number from 1 to 3; and c is a number from 1 to 8.

Preferably the compound of formula [A]ₐ[M]_{b}[X]_{c} comprises a perovskite. The compound of formula [A]ₐ[M]_{b}[X]_{c} often comprises a metal halide perovskite.

[M] comprises one or more M cations which are metal or metalloid cations. [M] may comprise two or more different M cations. [M] may comprise one or more monocations, one or more dications, one or more trications or one or more tetracations.

Typically, the one or more M cations are selected from Ca²⁺, Sr²⁺, Cd²⁺, Cu²⁺, Ni²⁺, Mn²⁺, Fe²⁺, Co²⁺, Pd²⁺, Ge²⁺, Sn²⁺, Pb²⁺, Yb²⁺, Eu²⁺, Bi³*, Sb³⁺, Pd⁴⁺, W⁴⁺, Re⁴⁺, Os⁴, Ir⁴⁺, Pt⁴⁺, Sn⁴⁺, Pb⁴⁺, Ge⁴⁺ or Te⁴⁺. Preferably, the one or more M cations are selected from Cu²⁺, Pb²⁺, Ge²⁺ or Sn²⁺.

Typically, [M] comprises one or more metal or metalloid dications. For instance, each M cation may be selected from Ca²⁺, Sr²⁺, Cd²⁺, Cu²⁺, Ni²⁺, Mn²⁺, Fe²⁺, Co²⁺, Pd²⁺, Ge²⁺, Sn²⁺, Pb²⁺, Yb²⁺ and Eu²⁺, preferably Sn²⁺, Pb²⁺, Cu²⁺, Ge²⁺, and Ni²⁺; preferably Sn²⁺ and Pb²⁺.

In some embodiments, [M] comprises two different M cations, typically where said cations are Sn²⁺ and Pb²⁺, preferably Pb²⁺.

In general, said one or more A cations are monocations. [A] typically comprises one or more A cations which may be organic and/or inorganic monocations. Typically, [A] comprises two or more different A cations. Typically, [A] comprises one or more A cations including at least one organic cation.

For instance, [A] may comprise at least two A cations which may be organic and/or inorganic monocations, or at least three A cations which may be organic and/or inorganic monocations. Thus, the compound of formula [A]ₐ[M]_{b}[X]_{c} may be a mixed cation perovskite. [A] may comprise at least one A cation which is an organic cation and at least one A cation which is an inorganic cation. [A] may comprise at least two A cations which are both organic cations. [A] may comprise at least two A cations which are both inorganic cations. In one embodiment, [A] comprises two A cations which are both organic cations and an A cation which is an inorganic cation.

Where an A species is an inorganic monocation, A is typically an alkali metal monocation (that is, a monocation of a metal found in Group 1 of the periodic table), for instance Li⁺, Na⁺, K⁺, Rb⁺, Cs⁺, for example Cs⁺ or Rb⁺. Typically, [A] comprises at least one organic monocation. Where an A species is an organic monocation, A is typically an ammonium cation, for instance methylammonium, or an iminium cation, for instance formamidimium.

Thus, typically each A cation is selected from: an alkali metal cation, for instance Li+, Na+, K+, Rb+, Cs+; a cation of the formula [R₁R₂R₃R₄N]⁺, wherein each of R₁, R₂, R₃, R₄ is independently selected from hydrogen, unsubstituted or substituted C₁₋₂₀ alkyl, and unsubstituted or substituted C₆₋₁₂ aryl, and at least one of R₁, R₂, R₃ and R₄ is not hydrogen; a cation of the formula [R₅R₆N═CH—NR₇R₈]⁺, wherein each of R₅, R₆, R₇ and R₈ is independently selected from hydrogen, unsubstituted or substituted C₁₋₂₀ alkyl, and unsubstituted or substituted C₆₋₁₂ aryl; and C₁₋₁₀ alkylamammonium, C₂₋₁₀ alkenylammonium, C₁₋₁₀ alkyliminium, C₃₋₁₀ cycloalkylammonium and C₃₋₁₀ cycloalkyliminium, each of which is unsubstituted or substituted with one or more substituents selected from amino, C₁₋₆ alkylamino, imino, C₁₋₆ alkylimino, C₁₋₆ alkyl, C₂₋₆ alkenyl, C₃₋₆ cycloalkyl and C₆₋₁₂ aryl.

For instance, each A cation is selected from Cs⁺, Rb⁺, methylammonium [(CH₃NH₃)⁺], ethylammonium [(CH₃CH₂NH₃)⁺], propylammonium [(CH₃CH₂CH₂NH₃)⁺], butylammonium [(CH₃CH₂CH₂CH₂NH₃)⁺], pentylammoium [(CH₃CH₂CH₂CH₂CH₂NH₃)⁺], hexylammonium [(CH₃CH₂CH₂CH₂CH₂CH₂NH₃)⁺], heptylammonium[(CH₃CH₂CH₂CH₂CH₂CH₂CH₂NH₃)⁺], octylammonium [(CH₃CH₂CH₂CH₂CH₂CH₂CH₂CH₂NH₃)⁺], tetramethylammonium [(N(CH₃)₄)⁺], formamidinium [(H₂N—C(H)═NH₂)⁺], 1-aminoethan-1-iminium [(H₂N—C(CH₃)═NH₂)⁺] and guanidinium [(H₂N—C(NH₂)═NH₂)⁺]. Preferably each A cation is selected from Cs⁺, Rb⁺, methylammonium, ethylammonium, propylammonium. butylammonium, pentylammoium, hexylammonium, heptylammonium, octylammonium, formamidinium and guanidinium.

[A] usually comprises one, two or three A monocations. [A] may comprises a single cation selected from methylammonium [(CH₃NH₃)⁺], ethylammonium [(CH₃CH₂NH₃)⁺], propylammonium [(CH₃CH₂CH₂NH₃)+], dimethylammonium [(CH₃)₂NH⁺], tetramethylammonium [(N(CH₃)₄)⁺], formamidinium [(H₂N—C(H)═NH2)+], 1-aminoethan-1-iminium [(H₂N—C(CH₃)═NH₂)⁺], guanidinium [(H₂N—C(NH₂)═NH₂)⁺], Cs⁺ and Rb⁺. For instance [A] may comprise a single cation that is methylammonium [(CH₃NH₃)⁺].

Alternatively, [A] may comprise two cations selected from this group, for instance Cs⁺ and formamidinium [(H₂N—C(H)═NH₂)⁺], or for instance Cs⁺ and Rb⁺, or for instance methylammonium [(CH₃NH₃)⁺] and formamidinium [(H₂N—C(H)═NH₂)⁺], preferably Cs⁺ and formamidinium [(H₂N—C(H)═NH₂)⁺].

Alternatively, [A] may comprise three cations selected from this group, for instance methylammonium [(CH₃NH₃)⁺], formamidinium [(H₂N—C(H)═NH₂)⁺] and Cs⁺.

[X] comprises one or more X anions. Typically, [X] comprises one or more halide anions, i.e. an anion selected from F⁻, Br⁻, Cl⁻ and I⁻. Typically, each X anion is a halide. [X] typically comprises one, two or three X anions and these are generally selected from Br⁻, Cl⁻ and I⁻.

X may comprise two more different X anions. Typically, [X] comprises two or more different halide anions. [X] may for instance consist of two X anions, such as Cl and Br, or Br and I, or Cl and I. Therefore, the compound of formula [A]ₐ[M]_{b}[X]_{c} often comprises a mixed halide perovskite. When [A] comprises one or more organic cations, the compound of formula [A]ₐ[M]_{b}[X]_{c} may be an organic-inorganic metal halide perovskite.

Typically, said one or more A cations are monocations, said one or more M cations are dications, and said one or more X anions are one or more halide anions.

Often, [A] comprises at least two different A cations as described herein and [X] comprises at least two different X anions as described herein. In some embodiments, [A] comprises at least three different A cations as described herein and [X] comprises at least two different X anions as described herein.

Typically, a=1, b=1 and c=3. Thus, the compound of formula [A]ₐ[M]_{b}[X]_{c} may be a compound of formula [A][M][X]₃, wherein [A], [M] and [X] are as described herein. Typically, the crystalline A/M/X material comprises: a perovskite of formula (I):

[A][M][X]₃ (I)

wherein: [A] comprises one or more A cations which are monocations; [M] comprises one or more M cations which are metal or metalloid dications; and [X] comprises one or more anions which are halide anions.

In some embodiments, the perovskite of formula (I) comprises a single A cation, a single M cation and a single X cation, i.e., the perovskite is a perovskite of the formula (IA):

AMX₃ (IA)

wherein A, M and X are as defined above. In a preferred embodiment, A is selected from (CH₃NH₃)⁺, (CH₃CH₂NH₃)⁺, (CH₃CH₂CH₂NH₃)⁺, (N(CH₃)₄)⁺, (H₂N—C(H)═NH₂)⁺, (H₂N—C(CH₃)═NH₂)⁺, (H₂N—C(NH₂)═NH₂)⁺, CS⁺ and Rb⁺; M is Pb²⁺ or Sn²⁺ and X is selected from Br⁻, Cl⁻ and I⁻.

For instance, the crystalline A/M/X material may comprise, or consist essentially of, a perovskite compound of formula (IA) selected from APbI₃, APbBr₃, APbCl₃, ASnI₃, ASnBr₃ and ASnCl₃, wherein A is a cation as described herein.

For instance, the crystalline A/M/X material may comprise, or consist essentially of, a perovskite compound of formula (IA) selected from CH₃NH₃PbI₃, CH₃NH₃PbBr₃, CH₃NH₃PbCl₃, CH₃NH₃SnI₃, CH₃NH₃SnBr₃, CH₃NH₃SnCl₃, CsPbI₃, CsPbBr₃, CsPbCl₃, CsSnI₃, CsSnBr₃, CsSnCl₃, (H₂N—C(H)═NH₂)PbI₃, (H₂N—C(H)═NH₂)PbBr₃, (H₂N—C(H)═NH₂)PbCl₃, (H₂N—C(H)═NH₂)SnI₃, (H₂N—C(H)═NH₂)SnBr₃ and (H₂N—C(H)═NH₂)SnCl₃, in particular CH₃NH₃PbI₃ or CH₃NH₃PbBr₃, preferably CH₃NH₃PbI₃.

In one embodiment, the perovskite is a perovskite of the formula (IB):

[A^{I}ₓA^{II}₁₋ₓ]MX₃ (IB)

wherein A^{I} and A^{II} are as defined above with respect to A, wherein M and X are as defined above and wherein x is greater than 0 and less than 1. In a preferred embodiment, A^{I} and A^{II} are each selected from (CH₃NH₃)⁺, (CH₃CH₂NH₃)⁺, (CH₃CH₂CH₂NH₃)⁺, (N(CH₃)₄)⁺, (H₂N—C(H)═NH₂)⁺, (H₂N—C(CH₃)═NH₂)⁺, (H₂N—C(NH₂)═NH₂)⁺, CS⁺ and Rb⁺; M is Pb²⁺ or Sn²⁺ and X is selected from Br⁻, Cl⁻ and I⁻. A^{I} and A^{II} may for instance be (H₂N—C(H)═NH₂)⁺ and Cs⁺ respectively, or they may be (CH₃NH₃)⁺ and (H₂N—C(H)═NH₂)⁺ respectively. Alternatively, they may be Cs⁺ and Rb⁺ respectively. Preferably, A^{I} and A^{II} are (H₂N—C(H)═NH₂)⁺ and Cs⁺ respectively

For instance, the crystalline A/M/X material may comprise, or consist essentially of, a perovskite compound of formula (IB) selected from (CsₓRb₁₋ₓ)PbBr₃, (CsₓRb₁₋ₓ)PbCl₃, (CsₓRb₁₋ₓ)PbI₃, [(CH₃NH₃)ₓ(H₂N—C(H)═NH₂)₁₋ₓ]PbCl₃, [(CH₃NH₃)ₓ(H₂N—C(H)═NH₂)₁₋ₓ]PbBr₃, [(CH₃NH₃)ₓ(H₂N—C(H)═NH₂)₁₋ₓ]PbI₃, [(CH₃NH₃)ₓCs₁₋ₓ]PbCl₃, [(CH₃NH₃)ₓCs₁₋ₓ]PbBr₃, [(CH₃NH₃)ₓCs₁₋ₓ]PbI₃, [(H₂N—C(H)═NH₂)ₓCs₁₋ₓ]PbCl₃, [(H₂N—C(H)═NH₂)ₓCs₁₋ₓ]PbBr₃, [(H₂N—C(H)═NH₂)ₓCs₁₋ₓ]PbI₃, [(CH₃NH₃)ₓ(H₂N—C(H)═NH₂)₁₋ₓ]SnCl₃, [(CH₃NH₃)ₓ(H₂N—C(H)═NH₂)₁₋ₓ]SnBr₃, [(CH₃NH₃)ₓ(H₂N—C(H)═NH₂)₁₋ₓ]SnI₃, [(CH₃NH₃)ₓCs₁₋ₓ]SnCl₃, [(CH₃NH₃)ₓCs₁₋ₓ]SnBr₃, [(CH₃NH₃)ₓCs₁₋ₓ]SnI₃, [(H₂N—C(H)═NH₂)ₓCs₁₋ₓ]SnCl₃, [(H₂N—C(H)═NH₂)ₓCs₁₋ₓ]SnBr₃, and [(H₂N—C(H)═NH₂)ₓCs₁₋ₓ]SnI₃, where x is greater than 0 and less than 1, for instance x may be from 0.01 to 0.99 or from 0.05 to 0.95 or 0.1 to 0.9.

In one embodiment, the perovskite is a perovskite compound of the formula (IC):

AM[X^{I}_{y}X^{II}_{1-y}]₃ (IC)

wherein A and M are as defined above, wherein X^{I} and X^{II} are as defined above in relation to X and wherein y is greater than 0 and less than 1. In a preferred embodiment, A is selected from (CH₃NH₃)⁺, (CH₃CH₂NH₃)⁺, (CH₃CH₂CH₂NH₃)⁺, (N(CH₃)₄)⁺, (H₂N—C(H)═NH₂)⁺, (H₂N—C(CH₃)═NH₂)⁺, (H₂N—C(NH₂)═NH₂)⁺, CS⁺ and Rb⁺; M is Pb²⁺ or Sn²⁺; and X^{I} and X^{II} are each selected from Br⁻, Cl⁻ and I⁻.

For instance, the crystalline A/M/X material may comprise, or consist essentially of, a perovskite compound of formula (IC) selected from APb[Br_{y}I_{1-y}]₃, APb[Br_{y}Cl_{1-y}]₃, APb[I_{y}Cl_{1-y}]₃, ASn[Br_{y}I_{1-y}]₃, ASn[Br_{y}Cl_{1-y}]₃, ASn[I_{y}Cl_{1-y}]₃, preferably APb[Br_{y}I_{1-y}]₃, where y is greater than 0 and less than 1, and wherein A is a cation as described herein, y may be from 0.01 to 0.99. For instance, y may be from 0.05 to 0.95 or 0.1 to 0.9.

For instance, the crystalline A/M/X material may comprise, or consist essentially of, a perovskite compound of formula (IC) selected from CH₃NH₃Pb[Br_{y}I_{1-y}]₃, CH₃NH₃Pb[Br_{y}Cl_{1-y}]₃, CH₃NH₃Pb[I_{y}Cl_{1-y}]₃, CH₃NH₃Sn[Br_{y}I_{1-y}]₃, CH₃NH₃Sn[Br_{y}Cl_{1-y}]₃, CH₃NH₃Sn[I_{y}Cl_{1-y}]₃, CsPb[Br_{y}I_{1-y}]₃, CsPb[Br_{y}Cl_{1-y}]₃, CsPb[I_{y}Cl_{1-y}]₃, CsSn[Br_{y}I_{1-y}]₃, CsSn[Br_{y}Cl_{1-y}]₃, CsSn[IᵥCl_{1-y}]₃, (H₂N—C(H)═NH₂)Pb[Br_{y}I_{1-y}]₃, (H₂N—C(H)═NH₂)Pb[Br_{y}Cl_{1-y}]₃, (H₂N—C(H)═NH₂)Pb[I_{y}Cl_{1-y}]₃, (H₂N—C(H)═NH₂)Sn[Br_{y}I_{1-y}]₃, (H₂N—C(H)═NH₂)Sn[Br_{y}Cl_{1-y}]₃, and (H₂N—C(H)═NH₂)Sn[I_{y}Cl_{1-y}]₃, where y is greater than 0 and less than 1, for instance y may be from 0.01 to 0.99 or from 0.05 to 0.95 or 0.1 to 0.9.

In a preferred embodiment, the perovskite is a perovskite of the formula (ID):

[A^{I}ₓA^{II}₁₋ₓ]M[X^{I}_{y}X^{II}_{1-y}]₃ (ID)

wherein A^{I} and A^{II} are as defined above with respect to A, M is as defined above, X^{I} and X^{II} are as defined above in relation to X and wherein x and y are both greater than 0 and less than 1. In a preferred embodiment, A^{I} and A^{II} are each selected from ((CH₃NH₃)⁺, (CH₃CH₂NH₃)⁺, (CH₃CH₂CH₂NH₃)⁺, (N(CH₃)₄)⁺, (H₂N—C(H)═NH₂)⁺, (H₂N—C(CH₃)═NH₂)⁺, (H₂N—C(NH₂)═NH₂)⁺, CS⁺ and Rb⁺, preferably A^{I} and A^{II} are (H₂N—C(H)═NH₂)⁺ and Cs⁺ respectively; M is Pb²⁺ or Sn²⁺; and X^{I} and X^{II} are each selected from Br⁻, Cl⁻ and I⁻.

For instance, the crystalline A/M/X material may comprise, or consist essentially of, a perovskite compound of formula (ID) selected from (CsₓRb₁₋ₓ)Pb(Br_{y}Cl_{1-y})₃, (CsₓRb₁₋ₓ)Pb(Br_{y}I_{1-y})₃, and (CsₓRb₁₋ₓ)Pb(Cl_{y}I_{1-y})₃, [(CH₃NH₃)ₓ(H₂N—C(H)═NH₂)₁₋ₓ]Pb[Br_{y}I_{1-y}]₃, [(CH₃NH₃)ₓ(H₂N—C(H)═NH₂)₁₋ₓ]Pb[Br_{y}Cl_{1-y}]₃, [(CH₃NH₃)ₓ(H₂N—C(H)═NH₂)₁₋ₓ]Pb[I_{y}Cl_{1-y}]₃, [(CH₃NH₃)ₓCs₁₋ₓ]Pb[Br_{y}I_{1-y}]₃, [(CH₃NH₃)ₓCs₁₋ₓ]Pb[Br_{y}Cl_{1-y}]₃, [(CH₃NH₃)ₓCs₁₋ₓ]Pb[I_{y}Cl_{1-y}]₃, [(H₂N—C(H)═NH₂)ₓCs₁₋ₓ]Pb[Br_{y}I_{1-y}]₃, [(H₂N—C(H)═NH₂)ₓCs₁₋ₓ]Pb[Br_{y}Cl_{1-y}]₃, [(H₂N—C(H)═NH₂)ₓCs₁₋ₓ]Pb[I_{y}Cl_{1-y}]₃, [(CH₃NH₃)ₓ(H₂N—C(H)═NH₂)₁₋ₓ]Sn[Br_{y}I_{1-y}]₃, [(CH₃NH₃)ₓ(H₂N—C(H)═NH₂)₁₋ₓ]Sn[Br_{y}Cl_{1-y}]₃, [(CH₃NH₃)ₓ(H₂N—C(H)═NH₂)₁₋ₓ]Sn[I_{y}Cl_{1-y}]₃, [(CH₃NH₃)ₓCs₁₋ₓ]Sn[Br_{y}I_{1-y}]₃, [(CH₃NH₃)ₓCs₁₋ₓ]Sn[Br_{y}Cl_{1-y}]₃, [(CH₃NH₃)ₓCs₁₋ₓ]Sn[I_{y}Cl_{1-y}]₃, [(H₂N—C(H)═NH₂)ₓCs₁₋ₓ]Sn[Br_{y}I_{1-y}]₃, [(H₂N—C(H)═NH₂)ₓCs₁₋ₓ]Sn[Br_{y}Cl_{1-y}]₃, and [(H₂N—C(H)═NH₂)ₓCs₁₋ₓ]Sn[I_{y}Cl_{1-y}]₃, where x and y are both greater than 0 and less than 1, for instance x and y may both be from 0.01 to 0.99 or from 0.05 to 0.95 or 0.1 to 0.9. Preferably, the compound of Formula (ID) is [(H₂N—C(H)═NH₂)ₓCs₁₋ₓ]Pb[Br_{y}I_{1-y}]₃.

In one embodiment, the perovskite is a perovskite of the formula (IE):

A[M^{I}_{z}M^{II}_{1-z}]X₃ (IE)

wherein M^{I} and M^{II} are as defined above with respect to M, A and X are as defined above, and wherein z is greater than 0 and less than 1. In a preferred embodiment, A is selected from (CH₃NH₃)⁺, (CH₃CH₂NH₃)⁺, (CH₃CH₂CH₂NH₃)⁺, (N(CH₃)₄)⁺, (H₂N—C(H)═NH₂)⁺, (H₂N—C(CH₃)═NH₂)⁺, (H₂N—C(NH₂)═NH₂)⁺, CS⁺ and Rb⁺; M¹ is Pb²⁺ and M^{II} is Sn²⁺; and X is selected from Br⁻, Cl⁻ and I⁻.

For instance, the crystalline A/M/X material may comprise, or consist essentially of, a perovskite compound of formula (IE) selected from CH₃NH₃[Pb_{z}Sn_{1-z}]Cl₃, CH₃NH₃[Pb_{z}Sn_{1-z}]Br₃, CH₃NH₃[Pb_{z}Sn_{1-z}]I₃, Cs[Pb_{z}Sn_{1-z}]Cl₃, Cs[Pb_{z}Sn_{1-z}]Br₃, Cs[Pb_{z}Sn_{1-z}]I₃, (H₂N—C(H)═NH₂)[Pb_{z}Sn_{1-z}]Cl₃, (H₂N—C(H)═NH₂)[Pb_{z}Sn_{1-z}]Br₃, and (H₂N—C(H)═NH₂)[Pb_{z}Sn_{1-z}]I₃, where z is greater than 0 and less than 1, for instance z may be from 0.01 to 0.99 or from 0.05 to 0.95 or 0.1 to 0.9.

In one embodiment, the perovskite is a perovskite of the formula (IF):

[A^{I}ₓA^{II}₁₋ₓ][M^{I}_{z}M^{II}_{1-z}]X₃ (IF)

wherein A^{I} and A^{II} are as defined above with respect to A, M^{I} and M^{II} are as defined above with respect to M, and X is as defined above and wherein x and z are both greater than 0 and less than 1. In a preferred embodiment, A^{I} and A^{II} are each selected from (CH₃NH₃)⁺, (CH₃CH₂NH₃)⁺, (CH₃CH₂CH₂NH₃)⁺, (N(CH₃)₄)⁺, (H₂N—C(H)═NH₂)⁺, (H₂N—C(CH₃)═NH₂)⁺, (H₂N—C(NH₂)═NH₂)⁺, CS⁺ and Rb⁺; M¹ is Pb²⁺ and Mⁿ is Sn²⁺; and X is selected from Br⁻, Cl⁻ and I⁻. A^{I} and A^{II} may for instance be (H₂N—C(H)═NH₂)⁺ and Cs⁺ respectively, or they may be (CH₃NH₃)⁺ and (H₂N—C(H)═NH₂)⁺ respectively. Alternatively, they may be Cs⁺ and Rb⁺ respectively.

For instance, the crystalline A/M/X material may comprise, or consist essentially of, a perovskite compound of formula (IF) selected from [(CH₃NH₃)ₓ(H₂N—C(H)═NH₂)₁₋ₓ][Pb_{z}Sn_{1-z}]Cl₃, [(CH₃NH₃)ₓ(H₂N—C(H)═NH₂)₁₋ₓ][Pb_{z}Sn_{1-z}]Br₃, [(CH₃NH₃)ₓ(H₂N—C(H)═NH₂)₁₋ₓ][Pb_{z}Sn_{1-z}]I₃, [(CH₃NH₃)ₓCs₁₋ₓ][Pb_{z}Sn_{1-z}]Cl₃, [(CH₃NH₃)ₓCs₁₋ₓ][Pb_{z}Sn_{1-z}]Br₃, [(CH₃NH₃)ₓCs₁₋ₓ][Pb_{z}Sn_{1-z}]I₃, [(H₂N—C(H)═NH₂)ₓCs₁₋ₓ][Pb_{z}Sn_{1-z}]Cl₃, [(H₂N—C(H)═NH₂)ₓCs₁₋ₓ][Pb_{z}Sn_{1-z}]Br₃, [(H₂N—C(H)═NH₂)ₓCs₁₋ₓ][Pb_{z}Sn_{1-z}]I₃, where x and z are both greater than 0 and less than 1, for instance x and z may each be from 0.01 to 0.99 or from 0.05 to 0.95 or 0.1 to 0.9. Preferably, the compound of Formula (IF) is [(CH₃NH₃)ₓCs₁₋ₓ][Pb_{z}Sn_{1-z}]I₃ or [(H₂N—C(H)═NH₂)ₓCs₁₋ₓ][Pb_{z}Sn_{1-z}]I3, wherein x and z may each be from 0.01 to 0.99 or from 0.05 to 0.95 or 0.1 to 0.9, typically where x is from 0.95 to 0.70 and z is from 0.25 to 0.75.

In one embodiment, the perovskite is a perovskite compound of the formula (IG):

A[M^{I}_{z}M^{II}_{1-z}][X^{I}_{y}X^{II}_{1-y}]₃ (IG)

wherein A is as defined above, M^{I} and M^{II} are as defined above with respect to M, and wherein X^{I} and X^{II} are as defined above in relation to X and wherein y and z are both greater than 0 and less than 1. In a preferred embodiment, A is selected from (CH₃NH₃)⁺, (CH₃CH₂NH₃)⁺, (CH₃CH₂CH₂NH₃)⁺, (N(CH₃)₄)⁺, (H₂N—C(H)═NH₂)⁺, (H₂N—C(CH₃)═NH₂)⁺, (H₂N—C(NH₂)═NH₂)⁺, CS⁺ and Rb⁺; M¹ is Pb²⁺ and Mⁿ is Sn²⁺; and X^{I} and X^{II} are each selected from Br⁻, Cl⁻ and I⁻.

For instance, the crystalline A/M/X material may comprise, or consist essentially of, a perovskite compound of formula (IG) selected from A[Pb_{z}Sn_{1-z}][Br_{y}I_{1-y}]₃, A[Pb_{z}Sn_{1-z}][Br_{y}Cl_{1-y}]₃, A[Pb_{z}Sn_{1-z}][I_{y}Cl_{1-y}]₃, where y and z are both greater than 0 and less than 1, and wherein A is a cation as described herein, y and z may each be from 0.01 to 0.99. For instance, y and z may each be from 0.05 to 0.95 or 0.1 to 0.9.

For instance, the crystalline A/M/X material may comprise, or consist essentially of, a perovskite compound of formula (IG) selected from CH₃NH₃[Pb_{z}Sn_{1-z}][Br_{y}I_{1-y}]₃, CH₃NH₃[Pb_{z}Sn_{1-z}][Br_{y}Cl_{1-y}]₃, CH₃NH₃[Pb_{z}Sn_{1-z}][I_{y}Cl_{1-y}]₃, Cs[Pb_{z}Sn_{1-z}][Br_{y}I_{1-y}]₃, Cs[Pb_{z}Sn_{1-z}][Br_{y}Cl_{1-y}]₃, Cs[Pb_{z}Sn_{1-z}][I_{y}Cl_{1-y}]₃, (H₂N—C(H)═NH₂)[Pb_{z}Sn_{1-z}][Br_{y}I_{1-y}]₃, (H₂N—C(H)═NH₂)[Pb_{z}Sn_{1-z}][Br_{y}Cl_{1-y}]₃, and (H₂N—C(H)═NH₂)[Pb_{z}Sn_{1-z}][I_{y}Cl_{1-y}]₃, where y and z are both greater than 0 and less than 1, for instance y and z may each be from 0.01 to 0.99 or from 0.05 to 0.95 or 0.1 to 0.9.

In a preferred embodiment, the perovskite is a perovskite of the formula (IH):

[A^{I}ₓA^{II}₁₋ₓ][M^{I}_{z}M^{II}_{1-z}][X^{I}_{y}X^{II}_{1-y}]₃ (IH)

wherein A^{I} and A^{II} are as defined above with respect to A, M^{I} and M^{II} are as defined above with respect to M, X^{I} and X^{II} are as defined above in relation to X and wherein x, y and z are each greater than 0 and less than 1. In a preferred embodiment, A^{I} and A^{II} are each selected from ((CH₃NH₃)⁺, (CH₃CH₂NH₃)⁺, (CH₃CH₂CH₂NH₃)⁺, (N(CH₃)₄)⁺, (H₂N—C(H)═NH₂)⁺, (H₂N—C(CH₃)═NH₂)⁺, (H₂N—C(NH₂)═NH₂)⁺, CS⁺ and Rb⁺; M¹ is Pb²⁺ and Mⁿ is Sn²⁺; and X^{I} and X^{II} are each selected from Br⁻, Cl⁻ and I⁻.

For instance, the crystalline A/M/X material may comprise, or consist essentially of, a perovskite compound of formula (IH) selected from [(CH₃NH₃)ₓ(H₂N—C(H)═NH₂)₁₋ₓ][Pb_{z}Sn_{1-z}][Br_{y}I_{1-y}]₃, [(CH₃NH₃)ₓ(H₂N—C(H)═NH₂)₁₋ₓ][Pb_{z}Sn_{1-z}][Br_{y}Cl_{1-y}]₃, [(CH₃NH₃)ₓ(H₂N—C(H)═NH₂)₁₋ₓ][Pb_{z}Sn_{1-z}][I_{y}Cl_{1-y}]₃, [(CH₃NH₃)ₓCs₁₋ₓ][Pb_{z}Sn_{1-z}][Br_{y}I_{1-y}]₃, [(CH₃NH₃)ₓCs₁₋ₓ][Pb_{z}Sn_{1-z}][Br_{y}Cl_{1-y}]₃, [(CH₃NH₃)ₓCs₁₋ₓ][Pb_{z}Sn_{1-z}][I_{y}Cl_{1-y}]₃, [(H₂N—C(H)═NH₂)ₓCs₁₋ₓ][Pb_{z}Sn_{1-z}][Br_{y}I_{1-y}]₃, [(H₂N—C(H)═NH₂)ₓCs₁₋ₓ][Pb_{z}Sn_{1-z}][Br_{y}Cl_{1-y}]₃, and [(H₂N—C(H)═NH₂)ₓCs₁₋ₓ][Pb_{z}Sn_{1-z}][I_{y}Cl_{1-y}]₃, where x, y and z are each greater than 0 and less than 1, for instance x, y and z may each be from 0.01 to 0.99 or from 0.05 to 0.95 or 0.1 to 0.9.

In one embodiment, a=2, b=1 and c=4. In that embodiment, the crystalline A/M/X material comprises a compound (a “2D layered perovskite”) of formula (II):

[A]₂[M][X]₄ (II)

wherein: [A] comprises one or more A cations which are monocations; [M] comprises one or more M cations which are metal or metalloid dications; and [X] comprises one or more X anions which are halide anions. In this embodiment, the A and M cations, and the X anions, are as defined above.

Ruddleson-Popper phase refers to a perovskite with a mixture of layered and 3D components. Typically, the layered 2D components may be of formula (II). Such perovskites may adopt the crystal structure, Aₙ₋₁A′₂MₙX₃ₙ₊₁, where A and A′ are different A cations, as described herein, M is one or more M cations, as described herein, X is one or more X anions, as described herein, and n is an integer from 1 to 8, or from 2 to 6. The term “mixed 2D and 3D” perovskite is used to refer to a perovskite film within which there exists both regions, or domains, of AMX₃ and Aₙ₋₁A′₂MₙX₃ₙ₊₁ perovskite phases, where A, M and X are all as described herein.

In another embodiment, a=2, b=1 and c=6. In that embodiment, the crystalline A/M/X material may in that case comprise a hexahalometallate of formula (III):

[A]₂[M][X]₆ (III)

wherein: [A] comprises one or more A cations which are monocations; [M] comprises one or more M cations which are metal or metalloid tetracations; and [X] comprises one or more X anions which are halide anions.

The hexahalometallate of formula (III) may in a preferred embodiment be a mixed monocation hexahalometallate. In a mixed monocation hexahalometallate, [A] comprises at least two A cations which are monocations; [M] comprises at least one M cation which is a metal or metalloid tetracation (and typically [M] comprises a single M cation which is a metal or metalloid tetracation); and [X] comprises at least one X anion which is a halide anion (and typically [X] comprises a single halide anion or two types of halide anion). In a mixed metal hexahalometallate, [A] comprises at least one monocation (and typically [A] is a single monocation or two types of monocation); [M] comprises at least two metal or metalloid tetracations (for instance Ge⁴⁺ and Sn⁴⁺); and [X] comprises at least one halide anion (and typically [X] is a single halide anion or two types of halide anion). In a mixed halide hexahalometallate, [A] comprises at least one monocation (and typically [A] is a single monocation or two types of monocation); [M] comprises at least one metal or metalloid tetracation (and typically [M] is a single metal tetra cation); and [X] comprises at least two halide anions, for instance Br⁻ and Cl⁻ or Br⁻ and I⁻.

[A] may comprise at least one A monocation selected from any suitable monocations, such as those described above for a perovskite. In the case of a hexahalometallate, each A cation is typically selected from Li⁺, Na⁺, K⁺, Rb⁺, Cs⁺, NH₄⁺ and monovalent organic cations. Monovalent organic cations are singly positively charged organic cations, which may, for instance, have a molecular weight of no greater than 500 g/mol. For instance, [A] may be a single A cation which is selected from Li⁺, Na⁺, K⁺, Rb⁺, Cs⁺, NH₄⁺ and monovalent organic cations. [A] preferably comprises at least one A cation which is a monocation selected from Rb⁺, Cs⁺, NH₄⁺ and monovalent organic cations. For instance, [A] may be a single inorganic A monocation selected from Li⁺, Na⁺, K⁺, Rb⁺, Cs⁺ and NH₄⁺. In another embodiment, [A] may be at least one monovalent organic A cation. For instance, [A] may be a single monovalent organic A cation. In one embodiment, [A] is (CH₃NH₃)⁺. In another embodiment, [A] is (H₂N—C(H)═NH₂)⁺.

Preferably, [A] comprises two or more types of A cation. [A] may be a single A monocation, or indeed two A monocations, each of which is independently selected from K⁺, Rb⁺, Cs⁺, NH₄⁺, (CH₃NH₃)⁺, (CH₃CH₂NH₃)⁺, (CH₃CH₂CH₂NH₃)⁺, (N(CH₃)₄)⁺, (N(CH₂CH₃)₄)⁺, (N(CH₂CH₂CH₃)₄)⁺, (H₂N—C(H)═NH₂)⁺ and (H₂N—C(CH₃)═NH₂)⁺. [M] may comprise one or more M cations which are selected from suitable metal or metalloid tetracations. Metals include elements of groups 3 to 12 of the Periodic Table of the Elements and Ga, In, Tl, Sn, Pb, Bi and Po. Metalloids include Si, Ge, As, Sb, and Te. For instance, [M] may comprise at least one M cation which is a metal or metalloid tetracation selected from Ti⁴⁺, V⁴⁺, Mn⁴⁺, Fe⁴⁺, Co⁴⁺, Zr⁴⁺, Nb⁴⁺, Mo⁴⁺, Ru⁴⁺, Rh⁴⁺, Pd⁴⁺, Hf⁴⁺, Ta⁴⁺, W⁴⁺, Re⁴⁺, Os⁴⁺, Ir⁴⁺, Pt⁴⁺, Sn⁴⁺, Pb⁴⁺, Po⁴⁺, Si⁴⁺, Ge⁴⁺, and Te⁴⁺. Typically, [M] comprises at least one metal or metalloid tetracation selected from Pd⁴⁺, W⁴⁺, Re⁴⁺, Os⁴⁺, Ir⁴⁺, Pt⁴⁺, Sn⁴⁺, Pb⁴⁺, Ge⁴⁺, and Te⁴⁺. For instance, [M] may be a single metal or metalloid tetracation selected from Pd⁴⁺, W⁴⁺, Re⁴⁺, Os⁴⁺, Ir⁴⁺, Pt⁴⁺, Sn⁴⁺, Pb⁴⁺, Ge⁴⁺, and Te⁴⁺.

Typically, [M] comprises at least one M cation which is a metal or metalloid tetracation selected from Sn⁴⁺, Te⁴⁺, Ge⁴⁺ and Re⁴⁺. In one embodiment [M] comprises at least one M cation which is a metal or metalloid tetracation selected from Pb⁴⁺, Sn⁴⁺, Te⁴⁺, Ge⁴⁺ and Re⁴⁺. For instance, [M] may comprise an M cation which is at least one metal or metalloid tetracation selected from Pb⁴⁺, Sn⁴⁺, Te⁴⁺ and Ge⁴⁺. Preferably, [M] comprises at least one metal or metalloid tetracation selected from Sn⁴⁺, Te⁴⁺, and Ge⁴⁺. As discussed above, the hexahalometallate compound may be a mixed-metal or a single-metal hexahalometallate. Preferably, the hexahalometallate compound is a single-metal hexahalometallate compound. More preferably, [M] is a single metal or metalloid tetracation selected from Sn⁴⁺, Te⁴⁺, and Ge⁴⁺. For instance, [M] may be a single metal or metalloid tetracation which is Te⁴⁺. For instance, [M] may be a single metal or metalloid tetracation which is Ge⁴⁺. Most preferably, [M] is a single metal or metalloid tetracation which is Sn⁴⁺.

[X] may comprise at least one X anion which is a halide anion. [X] therefore comprises at least one halide anion selected from F⁻, Cl⁻, Br⁻ and I⁻. Typically, [X] comprises at least one halide anion selected from Cl⁻, Br⁻ and I⁻. The hexahalometallate compound may be a mixed-halide hexahalometallate or a single-halide hexahalometallate. If the hexahalometallate is mixed, [X] comprises two, three or four halide anions selected from F⁻, Cl⁻, Br⁻ and I⁻. Typically, in a mixed-halide compound, [X] comprises two halide anions selected from F⁻, Cl⁻, Br⁻ and I⁻.

In some embodiments, [A] is a single monocation and [M] is a single metal or metalloid tetracation. Thus, the crystalline A/M/X material may, for instance, comprise a hexahalometallate compound of formula (IIIA)

A₂M[X]₆ (IIIA)

wherein: A is a monocation; M is a metal or metalloid tetracation; and [X] is at least one halide anion. [X] may be one, two or three halide anions selected from F⁻, Cl⁻, Br⁻ and I⁻, and preferably selected from Cl⁻, Br⁻ and I⁻. In formula (IIIA), [X] is preferably one or two halide anions selected from Cl⁻, Br⁻ and I⁻.

The crystalline A/M/X material may, for instance, comprise, or consist essentially of, a hexahalometallate compound of formula (IIIB)

A₂MX_{6-y}X′_{y} (IIIB)

wherein: A is a monocation (i.e. the second cation); M is a metal or metalloid tetracation (i.e. the first cation); X and X′ are each independently a (different) halide anion (i.e. two second anions); and y is from 0 to 6. When y is 0 or 6, the hexahalometallate compound is a single-halide compound. When y is from 0.01 to 5.99 the compound is a mixed-halide hexahalometallate compound. When the compound is a mixed-halide compound, y may be from 0.05 to 5.95. For instance, y may be from 1.00 to 5.00.

The hexahalometallate compound may, for instance, be A₂SnF_{6-y}Cl_{y}, A₂SnF_{6-y}Br_{y}, A₂SnF_{6-y}I_{y}, A₂SnCl_{6-y}Br_{y}, A₂SnCl_{6-y}I_{y}, A₂SnBr_{6-y}I_{y}, A₂TeF_{6-y}Cl_{y}, A₂TeF_{6-y}Br_{y}, A₂TeF_{6-y}I_{y}, A₂TeCl_{6-y}Br_{y}, A₂TeCl_{6-y}I_{y}, A₂TeBr_{6-y}I_{y}, A₂GeF_{6-y}Cl_{y}, A₂GeF_{6-y}Br_{y}, A₂GeF_{6-y}I_{y}, A₂GeCl_{6-y}Br_{y}, A₂GeCl_{6-y}I_{y}, A₂GeBr_{6-y}I_{y}, A₂ReF_{6-y}Cl_{y}, A₂ReF_{6-y}Br_{y}, A₂ReF_{6-y}I_{y}, A₂ReCl_{6-y}Br_{y}, A₂ReCl_{6-y}I_{y} or A₂ReBr_{6-y}I_{y}, wherein: A is K⁺, Rb⁺, Cs⁺, (R¹NH₃)⁺, (NR²₄)⁺, or (H₂N—C(R¹)═NH₂)⁺, wherein R¹ is H, a substituted or unsubstituted C₁₋₂₀ alkyl group or a substituted or unsubstituted aryl group, and R² is a substituted or unsubstituted C₁₋₁₀ alkyl group; and y is from 0 to 6. Optionally, y is from 0.01 to 5.99. If the hexahalometallate compound is a mixed-halide compound, y is typically from 1.00 to 5.00. A may be as defined above. For instance, A may be Cs⁺, NH₄⁺, (CH₃NH₃)⁺, (CH₃CH₂NH₃)⁺, (N(CH₃)₄)⁺, (N(CH₂CH₃)₄)⁺, (H₂N—C(H)═NH₂)⁺ or (H₂N—C(CH₃)═NH₂)⁺, for instance Cs⁺, NH₄⁺, or (CH₃NH₃)⁺.

The hexahalometallate compound may typically be A₂SnF_{6-y}Cl_{y}, A₂SnF_{6-y}Br_{y}, A₂SnF_{6-y}I_{y}, A₂SnCl_{6-y}Br_{y}, A₂SnCl_{6-y}I_{y}, or A₂SnBr_{6-y}I_{y}, wherein: A is K⁺, Rb⁺, Cs⁺, (R¹NH₃)⁺, (NR²₄)⁺, or (H₂N—C(R¹)═NH₂)⁺, or A is as defined herein, wherein R¹ is H, a substituted or unsubstituted C₁₋₂₀ alkyl group or a substituted or unsubstituted aryl group, or R² is a substituted or unsubstituted C₁₋₁₀ alkyl group; and y is from 0 to 6.

In another embodiment, the hexahalometallate compound is A₂GeF_{6-y}Cl_{y}, A₂GeF_{6-y}Br_{y}, A₂GeF_{6-y}I_{y}, A₂GeCl_{6-y}Br_{y}, A₂GeCl_{6-y}I_{y}, or A₂GeBr_{6-y}I_{y}, wherein: A is K⁺, Rb⁺, Cs⁺, (R¹NH₃)⁺, (NR²₄)⁺, or (H₂N—C(R¹)═NH₂)⁺, or A is as defined herein, wherein R¹ is H, a substituted or unsubstituted C₁₋₂₀ alkyl group or a substituted or unsubstituted aryl group, and R² is a substituted or unsubstituted C₁₋₁₀ alkyl group; and y is from 0 to 6.

The hexahalometallate compound may, for instance, be A₂TeF_{6-y}Cl_{y}, A₂TeF_{6-y}Br_{y}, A₂TeF_{6-y}I_{y}, A₂TeCl_{6-y}Br_{y}, A₂TeCl_{6-y}I_{y}, or A₂TeBr_{6-y}I_{y}, wherein: A is K⁺, Rb⁺, Cs⁺, (R¹NH₃)⁺, (NR²₄)⁺, or (H₂N—C(R¹)═NH₂)⁺, or A is as defined herein, wherein R¹ is H, a substituted or unsubstituted C₁₋₂₀ alkyl group or a substituted or unsubstituted aryl group, and R² is a substituted or unsubstituted C₁₋₁₀ alkyl group; and y is from 0 to 6 or y is as defined herein.

Often, y will be from 1.50 to 2.50. For instance, y may be from 1.80 to 2.20. This may occur if the compound is produced using two equivalents of AX′ and one equivalent of MX₄, as discussed below.

In some embodiments, all of the ions are single anions or cations. Thus, the crystalline A/M/X material may comprise, or consist essentially of, a hexahalometallate compound of formula (IIIC)

A₂MX₆ (IIIC)

wherein: A is a monocation; M is a metal or metalloid tetracation; and X is a halide anion. A, M and X may be as defined herein.

The hexahalometallate compound may be A₂SnF₆, A₂SnCl₆, A₂SnBr₆, A₂SnI₆, A₂TeF₆, A₂TeCl₆, A₂TeBr₆, A₂TeI₆, A₂GeF₆, A₂GeCl₆, A₂GeBr₆, A₂GeI₆, A₂ReF₆, A₂ReCl₆, A₂ReBr₆ or A₂ReI₆, wherein: A is K⁺, Rb⁺, Cs⁺, (R¹NH₃)⁺, (NR²₄)⁺, or (H₂N—C(R¹)═NH₂)⁺, wherein R¹ is H, a substituted or unsubstituted C₁₋₂₀ alkyl group or a substituted or unsubstituted aryl group, and R² is a substituted or unsubstituted C₁₋₁₀ alkyl group. A may be as defined herein. Preferably, the hexahalometallate compound is Cs₂SnI₆, Cs₂SnBr₆, Cs₂SnBr_{6-y}I_{y}, Cs₂SnCl_{6-y}I_{y}, Cs₂SnCl_{6-y}Br_{y}, (CH₃NH₃)₂SnI₆, (CH₃NH₃)₂SnBr₆, (CH₃NH₃)₂SnBr_{6-y}I_{y}, (CH₃NH₃)₂SnCl_{6- y}I_{y}, (CH₃NH₃)₂SnCl_{6-y}Br_{y}, (H₂N—C(H)═NH₂)₂SnI₆, (H₂N—C(H)═NH₂)₂SnBr₆, (H₂N—C(H)═NH₂)₂SnBr_{6-y}I_{y}, (H₂N—C(H)═NH₂)₂SnCl_{6-y}I_{y} or (H₂N—C(H)═NH₂)₂SnCl_{6-y}Br_{y} wherein y is from 0.01 to 5.99. For example, the hexahalometallate compound may be (CH₃NH₃)₂SnI₆, (CH₃NH₃)₂SnBr₆, (CH₃NH₃)₂SnCl₆, (H₂N—C(H)═NH₂)₂SnI₆, (H₂N—C(H)═NH₂)₂SnBr₆ or (H₂N—C(H)═NH₂)₂SnCl₆. The hexahalometallate compound may be Cs₂SnI₆, Cs₂SnBr₆, Cs₂SnCl_{6-y}Br_{y}, (CH₃NH₃)₂SnI₆, (CH₃NH₃)₂SnBr₆, or (H₂N—C(H)═NH₂)₂SnI₆.

The crystalline A/M/X material may comprise a bismuth or antimony halogenometallate. For instance, the crystalline A/M/X material may comprise a halogenometallate compound comprising: (i) one or more monocations ([A]) or one or more dications ([B]); (ii) one or more metal or metalloid trications ([M]); and (iii) one or more halide anions ([X]). The compound may be a compound of formula BBiX₅, B₂BiX₇ or B₃BiX₉ where B is (H₃NCH₂NH₃)²⁺, (H₃N(CH₂)₂NH₃)²⁺, (H₃N(CH₂)₃NH₃)²⁺, (H₃N(CH₂)₄NH₃)²⁺, (H₃N(CH₂)₅NH₃)²⁺, (H₃N(CH₂)₆NH₃)²⁺, (H₃N(CH₂)₇NH₃)²⁺, (H₃N(CH₂)₈NH₃)²⁺ or (H₃N—C₆H₄—NH₃)²⁺ and X is I⁻, Br⁻ or Cl⁻, preferably I⁻.

In yet further embodiments, the crystalline A/M/X materials may be double perovskites. Such compounds are defined in WO 2017/037448, the entire contents of which is incorporated herein by reference. Typically, the compound is a double perovskite compound of formula (IV):

[A]₂[B⁺][B³⁺][X]₆ (IV);

wherein: [A] comprises one or more A cations which are monocations, as defined herein; [B⁺] and [B³⁺] are equivalent to [M] where M comprises one or more M cations which are monocations and one or more M cations which are trications; and [X] comprises one or more X anions which are halide anions.

The one or more M cations which are monocations comprised in [B⁺] are typically selected from metal and metalloid monocations. Preferably, the one or more M cations which are monocations are selected from Li⁺, Na⁺, K⁺, Rb⁺, Cs⁺, Cu⁺, Ag⁺, Au⁺ and Hg⁺. More preferably, the one or more M cations which are monocations are selected from Cu⁺, Ag⁺ and Au⁺. Most preferably, the one or more M cations which are monocations are selected from Ag⁺ and Au⁺. For instance, [B⁺] may be one monocation which is Ag⁺ or [B⁺] may be one monocation which is Au⁺.

The one or more M cations which are trications comprised in [B³⁺] are typically selected from metal and metalloid trications. Preferably, the one or more M cations which are trications are selected from Bi³⁺, Sb³⁺, Cr³⁺, Fe³⁺, Co³⁺, Ga³⁺, As³⁺, Ru³⁺, Rh³⁺, In³⁺, Ir³⁺ and Au³⁺. More preferably, the one or more M cations which are trications are selected from Bi³⁺ and Sb³⁺. For instance, [B³⁺] may be one trication which is Bi³⁺ or [B³⁺] may be one trication which is Sb³⁺. Bismuth has relatively low toxicity compared with heavy metals such as lead. In some embodiments, the one or more M cations which are monocations (in [B⁺]) are selected from Cu⁺, Ag⁺ and Au⁺ and the one or more M cations which are trications (in [B³⁺]) are selected from Bi³⁺ and Sb³⁺.

An exemplary double perovskite is Cs₂BiAgBr₆.

Typically, where the compound is a double perovskite it is a compound of formula (IVa):

A₂B⁺B³⁺[X]₆ (IVa);

wherein: the A cation is as defined herein; B⁺ is an M cation which is a monocation as defined herein; B³⁺ is an M cation which is a trication as defined herein; and [X] comprises one or more X anions which are halide anions, for instance two or more halide anions, preferably a single halide anion.

In yet another embodiment, the compound may be a layered double perovskite compound of formula (V):

[A]₄[B⁺][B³⁺][X]₈ (V);

wherein: [A], [B⁺], [B³⁺] and [X] are as defined above. In some embodiments, the layered double perovskite compound is a double perovskite compound of formula (Va):

A₄B⁺B³⁺[X]₈ (Va);

wherein: the A cation is as defined herein; B⁺ is an M cation which is a monocation as defined herein; B³⁺ is an M cation which is a trication as defined herein; and [X] comprises one or more X anions which are halide anions, for instance two or more halide anions, preferably a single halide anion or two kinds of halide anion.

In yet another embodiment, the compound may be a compound of formula (VI):

[A]₄[M][X]₆ (VI);

wherein: [A], [M] and [X] are as defined above (in relation to, for instance, compounds of formula (I) or (II)). However, preferably the compound is not a compound of formula (VI). Where the compound is a compound of formula (VI), the compound may preferably be a compound of formula (VIA)

[A^{I}A^{II}]₄[M][X]₆ (VIA);

that is, a compound wherein [A] comprises two types of A monoacation. In other preferred embodiments, the compound of formula (VI) may be a compound of formula (VIB):

[A]₄[M][X^{I}X^{II}]₆ (VIB);

that is, a compound of formula (VI) wherein [X] comprises two types of X anion. In yet other preferred embodiments, the compound of formula (VI) may be a compound of formula (VIC):

[A^{I}A^{II}]₄[M][X^{I}X^{II}]₆ (VIC);

that is, a compound of formula (VI) wherein [A] comprises two types of A monoacation and [X] comprises two types of X anion. In formulae (VIa), (VIb) and (VIc), each of: [A], [M] and [X] are as defined above (in relation to, for instance, compounds of formula (I) or (II)).

In another embodiment, a=1, b=1 and c=4. In that embodiment, the crystalline A/M/X material may in that case comprise a compound of formula (VII):

[A][M][X]₄ (VII)

wherein: [A] comprises one or more A cations which are monocations; [M] comprises one or more M cations which are metal or metalloid trications; and [X] comprises one or more X anions which are halide anions. The A monocations and M trications are as defined herein. An exemplary compound of formula (VII) is AgBiI₄.

Typically the first photoactive material comprises at least one first A/M/X material as described herein, and the second photoactive material comprises at least one second A/M/X material as described herein. Typically, the first photoactive material consists essentially of or consists of at least one first A/M/X material as described herein, and the second photoactive material consists essentially of or consists of at least one second A/M/X material as described herein. Preferably, the at least one first and second A/M/X materials are different. For instance, the first A/M/X material may be a compound of formula (I), (IA), (IB), (IC), (ID), (IE), (IF), (IG), (IH), (II), (III), (IV), (V), (VI) and (VII) as described above, and the second A/M/X material may be a different compound of formula (I), (IA), (IB), (IC), (ID), (IE), (IF), (IG), (IH), (II), (III), (IV), (V), (VI) and (VII) as described above.

Typically, the first photoactive material comprises a first A/M/X material where [X] comprises two or more X anions wherein each X anion is a halide, preferably wherein [X] comprises Br and I. [A] in the first A/M/X material may comprise two or more A cations, typically wherein one of the A cations is an organic cation. For example, [A] in the first A/M/X material may comprise Cs⁺ and formamidinium.

In one embodiment, the first A/M/X material may comprise a compound of formula (IC) as described herein, for instance APb[Br_{y}I_{1-y}]₃, where y is greater than 0 and less than 1, and wherein A is a cation as described herein, y may be from 0.01 to 0.99. y may be from 0.05 to 0.95 or 0.1 to 0.9. Typically, A is Cs+, thus the compound of Formula (IC) is CsPb[Br_{y}I_{1-y}]₃.

In another embodiment, the first A/M/X material may be a compound of formula (ID) as described herein, for instance a compound of formula [(H₂N—C(H)═NH₂)ₓCs₁₋ₓ]Pb[Br_{y}I_{1-y}]₃ where x and y are both greater than 0 and less than 1, for instance x and y may both be from 0.01 to 0.99 or from 0.05 to 0.95 or 0.1 to 0.9.

In another embodiment, the first A/M/X material comprises a compound of Formula (II). For instance, the first A/M/X material may comprise a mixed 2D and 3D perovskite as described herein.

Typically, the second photoactive material comprises a second A/M/X material wherein [M] in the second A/M/X material comprises two or more M cations. Preferably [M] comprises Pb²⁺ and Sn²⁺.

For instance, in one embodiment, the second A/M/X material comprises a compound of Formula (IE), as described herein, for instance CH₃NH₃[Pb_{z}Sn_{1-z}]Cl₃, CH₃NH₃[Pb_{z}Sn_{1-z}]Br₃, CH₃NH₃[Pb_{z}Sn_{1-z}]I₃, Cs[Pb_{z}Sn_{1-z}]Cl₃, Cs[Pb_{z}Sn_{1-z}]Br₃, Cs[Pb_{z}Sn_{1-z}]I₃, (H₂N—C(H)═NH₂)[Pb_{z}Sn_{1-z}]Cl₃, (H₂N—C(H)═NH₂)[Pb_{z}Sn_{1-z}]Br₃, and (H₂N—C(H)═NH₂)[Pb_{z}Sn_{1-z}]I₃, where z is greater than 0 and less than 1, for instance z may be from 0.01 to 0.99 or from 0.05 to 0.95 or 0.1 to 0.9.

In another embodiment, the second A/M/X material comprises a compound of Formula (IF), as described herein, for instance a compound of formula [(CH₃NH₃)ₓCs₁₋ₓ][Pb_{z}Sn_{1-z}]I₃ where x and z are both greater than 0 and less than 1, for instance x and z may each be from 0.01 to 0.99 or from 0.05 to 0.95 or 0.1 to 0.9.

In another embodiment, the second A/M/X material comprises a compound of Formula (IF) which is [(H₂N—C(H)═NH₂)ₓCs₁₋ₓ][Pb_{z}Sn_{1-z}]I₃, wherein x and z may each be from 0.01 to 0.99 or from 0.05 to 0.95 or 0.1 to 0.9, typically where x is from 0.95 to 0.70 and z is from 0.25 to 0.75.

In one embodiment, the first photoactive material comprises a first A/M/X material as described herein, and the second photoactive material comprises a compound comprising a chalcogenide anion, usually a metal chalcogenide, comprising at least one metal and at least one chalcogenide anion. For instance, the first photoactive material may be a compound of formula (ID) and the second photoactive material may be copper indium gallium selenide (CIGS) or copper indium sulphide (CIS). In one embodiment, the first photoactive material is a compound of formula [(H₂N—C(H)═NH₂)ₓCs₁₋ₓ]Pb[Br_{y}I_{1-y}]₃ where x and y are both greater than 0 and less than 1, for instance x and y may both be from 0.01 to 0.99 or from 0.05 to 0.95 or 0.1 to 0.9, for instance [(H₂N—C(H)═NH₂)_{0.8}Cs_{0.2}]Pb[Br_{0.1}I_{0.9}]₃, and the second photoactive material may be copper indium gallium selenide (CIGS) or copper indium sulphide (CIS).

Device Structure

Typically, in the multi-junction device of the present invention, the photoactive regions each further comprise one or more charge transporting layers. Typically, each photoactive region comprises at least two charge transporting layers.

The charge transporting layers may be electron transporting (n-type) layers or hole transporting (p-type) layers. Typically, each photoactive region comprises an electron transporting (n-type) layer and a hole transporting (p-type) layer,

Usually, each photoactive region comprises the layer of a photoactive material disposed between an electron transporting (n-type) layer and a hole transporting (p-type) layer. Thus, each photoactive region may comprise the following layers in the following order:
hole transporting (p-type) layer;
layer of a photoactive material, as described herein;
electron transporting (n-type) layer.

Hence, in one embodiment, the multi-junction device may comprise the following layers in the following order:
hole transporting (p-type) layer;
layer of a first photoactive material, as described herein;
electron transporting (n-type) layer;
charge recombination layer, as described herein;
hole transporting (p-type) layer;
layer of a second photoactive material, as described herein;
electron transporting (n-type) layer.

The n-type layers may comprise, consist essentially of consist of an electron transporting (n-type) material. Examples of electron transporting (n-type) materials are known to the skilled person. A suitable n-type material may be an organic or inorganic material. A suitable inorganic n-type material may be selected from a metal oxide, a metal sulphide, a metal selenide, a metal telluride, a perovskite, amorphous Si, an n-type group IV semiconductor, an n-type group III-V semiconductor, an n-type group II-VI semiconductor, an n-type group I-VII semiconductor, an n-type group IV-VI semiconductor, an n-type group V-VI semiconductor, and an n-type group II-V semiconductor, any of which may be doped or undoped. More typically, the n-type material is selected from a metal oxide, a metal sulphide, a metal selenide, and a metal telluride.

Thus, the n-type layer may comprise an inorganic material selected from oxide of titanium, tin, zinc, niobium, tantalum, tungsten, indium, gallium, neodymium, palladium, or cadmium, or an oxide of a mixture of two or more of said metals. For instance, the n-type layer may comprise TiO₂, SnO₂, ZnO, Nb₂O₅, Ta₂O₅, WO₃, W₂O₅, In₂O₃, Ga₂O₃, Nd₂O₃, PbO, or CdO. Other suitable n-type materials that may be employed include sulphides of cadmium, tin, copper, or zinc, including sulphides of a mixture of two or more of said metals. For instance, the sulphide may be FeS₂, CdS, ZnS, SnS, BiS, SbS, or Cu₂ZnSnS₄.

The n-type layer may for instance comprise a selenide of cadmium, zinc, indium, or gallium or a selenide of a mixture of two or more of said metals; or a telluride of cadmium, zinc, cadmium or tin, or a telluride of a mixture of two or more of said metals. For instance, the selenide may be Cu(In,Ga)Se₂. Typically, the telluride is a telluride of cadmium, zinc, cadmium or tin. For instance, the telluride may be CdTe.

The n-type layer may for instance comprise an inorganic material selected from oxide of titanium (e.g. TiO₂), tin (e.g. SnO₂), zinc (e.g. ZnO), niobium, tantalum, tungsten, indium, gallium, neodymium, palladium, cadmium, or an oxide of a mixture of two or more of said metals; a sulphide of cadmium, tin, copper, zinc or a sulphide of a mixture of two or more of said metals; a selenide of cadmium, zinc, indium, gallium or a selenide of a mixture of two or more of said metals; or a telluride of cadmium, zinc, cadmium or tin, or a telluride of a mixture of two or more of said metals.

Examples of other semiconductors that may be suitable n-type materials, for instance if they are n-doped, include group IV elemental or compound semiconductors; amorphous Si; group III-V semiconductors (e.g. gallium arsenide); group II-VI semiconductors (e.g. cadmium selenide); group I-VII semiconductors (e.g. cuprous chloride); group IV-VI semiconductors (e.g. lead selenide); group V-VI semiconductors (e.g. bismuth telluride); and group II-V semiconductors (e.g. cadmium arsenide).

Other n-type materials may also be employed, including organic and polymeric electron-transporting materials, and electrolytes. Suitable examples include, but are not limited to a fullerene or a fullerene derivative (for instance C₆₀, C₇₀, phenyl-C₆₁-butyric acid methyl ester (PCBM), PC₇₁BM (i.e. phenyl C₇₁ butyric acid methyl ester), bis[C₆₀]BM (i.e. bis-C₆₀ butyric acid methyl ester), and 1′,1″,4′,4″-Tetrahydro-di[1,4]methanonaphthaleno[1,2:2′,3′,56,60:2″,3″][5,6]fullerene-C₆₀ (ICBA)), an organic electron transporting material comprising perylene or a derivative thereof, poly{[N,N0-bis(2-octyldodecyl)-naphthalene-1,4,5,8-bis(dicarboximide)-2,6-diyl]-alt-5,50-(2,20-bithiophene)}(P(NDI2OD-T2)), bathocuproine (BCP) or C₆₀/BCP.

Typically, the n-type material is phenyl-C61-butyric acid methyl ester (PCBM) or C₆₀/BCP.

In some embodiments, the n-type layer may comprise two sub-layers each comprising an n-type material. For instance, the n-type layer may comprise a first sub-layer that comprises an organic n-type material, preferably PCBM, and a second sub-layer that comprises an inorganic n-type material, preferably SnO₂.

The p-type layers may comprise, consist essentially of consist of an hole transporting (p-type) material. Examples of hole transporting (p-type) materials are known to the skilled person.

The p-type material may be a single p-type compound or elemental material, or a mixture of two or more p-type compounds or elemental materials, which may be undoped or doped with one or more dopant elements.

The p-type material may comprise an inorganic or an organic p-type material. For instance, the p-type material may be an organic p-type material.

Suitable p-type materials may be selected from polymeric or molecular hole transporters. The p-type material may for instance comprise spiro-OMeTAD (2,2′,7,7′-tetrakis-(N,N-di-p-methoxyphenylamine)9,9′-spirobifluorene)), P3HT (poly(3-hexylthiophene)), PCPDTBT (Poly[2,1,3-benzothiadiazole-4,7-diyl[4,4-bis(2-ethylhexyl)-4H-cyclopenta[2,1-b:3,4-b′]dithiophene-2,6-diyl]]), PVK (poly(N-vinylcarbazole)), HTM-TFSI (1-hexyl-3-methylimidazolium bis(trifluoromethylsulfonyl)imide), Li-TFSI (lithium bis(trifluoromethanesulfonyl)imide), spiro-OMETAD⁺-bis(trifluoromethanesulfonyl)imide (spiro(TFSI)₂), tBP (tert-butylpyridine), m-MTDATA (4,4′,4″-tris(methylphenylphenylamino)triphenylamine), MeOTPD (N,N,N′,N′-tetrakis(4-methoxyphenyl)-benzidine), BP2T (5,5′-di(biphenyl-4-yl)-2,2′-bithiophene), Di-NPB (N,N′-Di-[(1-naphthyl)-N,N′-diphenyl]-1,1′-biphenyl)-4,4′-diamine), α-NPB (N,N′-di(naphthalen-1-yl)-N,N′-diphenyl-benzidine), TNATA (4,4′,4″-tris-(N-(naphthylen-2-yl)-N-phenylamine)triphenylamine), BPAPF (9,9-bis[4-(N,N-bis-biphenyl-4-yl-amino)phenyl]-9H-fluorene), spiro-NPB (N2,N7-Di-1-naphthalenyl-N2,N7-diphenyl-9,9′-spirobi[9H-fluorene]-2,7-diamine), 4P-TPD (4,4-bis-(N,N-diphenylamino)-tetraphenyl), polyTPD (i.e. Poly[N,N′-bis(4-butylphenyl)-N,N′-bisphenylbenzidine]), PTAA (i.e. poly(triaryl amine), also known as poly[bis(4-phenyl)(2,4,6-trimethylphenyl)amine]) or poly(3,4-ethylenedioxythiophene) polystyrene sulfonate (PEDOT:PSS). The p-type material may comprise carbon nanotubes. Usually, the p-type material is selected from spiro-OMeTAD, P3HT, PCPDTBT, polyTPD, PEDOT:PSS, spiro(TFSI)₂ and PVK.

Suitable p-type materials also include molecular hole transporters, polymeric hole transporters and copolymer hole transporters. The p-type material may for instance be a molecular hole transporting material, a polymer or copolymer comprising one or more of the following moieties: thiophenyl, phenelenyl, dithiazolyl, benzothiazolyl, diketopyrrolopyrrolyl, ethoxydithiophenyl, amino, triphenyl amino, carbozolyl, ethylene dioxythiophenyl, dioxythiophenyl, or fluorenyl.

The p-type material may be doped, for instance with tertbutyl pyridine and LiTFSI. The p-type material may be doped to increase the hole-density. The p-type material may for instance be doped with NOBF₄ (Nitrosonium tetrafluoroborate), to increase the hole-density.

Typically, the hole-transporting material (p-type material) is a solid state inorganic hole transporting material. For instance, the p-type layer may comprise an inorganic hole transporter comprising an oxide of nickel (e.g. NiO), vanadium, copper or molybdenum; CuI, CuBr, CuSCN, Cu₂O, CuO or CIS; a perovskite; amorphous Si; a p-type group IV semiconductor, a p-type group III-V semiconductor, a p-type group II-VI semiconductor, a p-type group I-VII semiconductor, a p-type group IV-VI semiconductor, a p-type group V-VI semiconductor, and a p-type group II-V semiconductor, which inorganic material may be doped or undoped. The p-type layer may be a compact layer of said inorganic hole transporter.

The p-type material may be an inorganic p-type material, for instance a material comprising an oxide of nickel, vanadium, copper or molybdenum; CuI, CuBr, CuSCN, Cu₂O, CuO or CIS; amorphous Si; a p-type group IV semiconductor, a p-type group III-V semiconductor, a p-type group II-VI semiconductor, a p-type group I-VII semiconductor, a p-type group IV-VI semiconductor, a p-type group V-VI semiconductor, and a p-type group II-V semiconductor, which inorganic material may be doped or undoped. The p-type material may for instance comprise an inorganic hole transporter selected from CuI, CuBr, CuSCN, Cu₂O, CuO and CIS.

Typically, the layer of a hole transporting (p-type) material is a solid state inorganic hole transporting material comprising an oxide of nickel, vanadium, copper or molybdenum. The solid state inorganic hole transporting material is typically present as a compact layer. For example, the solid state inorganic hole transporting material comprises nickel oxide, for instance, a compact layer of nickel oxide. The layer of a hole transporting (p-type) material may comprise two sub-layers, for example an inorganic p-type sublayer and an organic p-type sub-layer. The inorganic p-type sublayer may be a layer of nickel oxide. The organic p-type sub-layer maybe a layer of polyTPD.

The multi-junction device as described herein may further comprise one or more buffer layers. For instance, one or more buffer layers may be introduced between the electrodes and the charge transporting layers (electron transporting (n-type) layer or hole transporting (p-type) layer). The purpose of the buffer layers is to both improve the electronic and physical contact between the charge transporting layer and the electrode, and to prevent damage of the charge transporting and photoactive layers by or during the desposition of the electrode. Buffer layers may also prevent undesired chemical interactions occuring at points of physical contact between the electrode with the charge transporting and/or photoactive layers. Examples of buffer layers include individual layers, combinations of or alloys of SnO₂, ZnO, MoOₓ, Al₂O₃ Cr, CrO, LiF and BCP.

The multi-junction device as described herein may further comprise one or more interface modifying layers. Often, the properties of the surface of the perovskite layer, or the interface between the perovskite layer and the charge tansporting layer can be improved by the inclusion of at least one interface modifying layer. The improvement provided by the one or more interface modifying layers may be one of the following properties: slower surface recombination of charge; improved charge extraction; a shift in the energy level alignment at the interface inducing enhanced open-ciruit voltage; improved stability of the photoactive layer (for instance a layer of an A/M/X material as described herein), and/or improved stability of the A/M/X layer in contact with a charge extraction layer. The interface modifying layer or layers may comprise LiF; MgF₂; AX, where A=Cs, Rb, Na, K, and X═I, Br, Cl, or F; AX where A=organic ammonium cation as described herein, such as guanadinium, and X═I, Cl, Br, F, and pseudo halides; Al₂O₃, and other A/M/X passivation agents, such as those described in WO2015092397A1

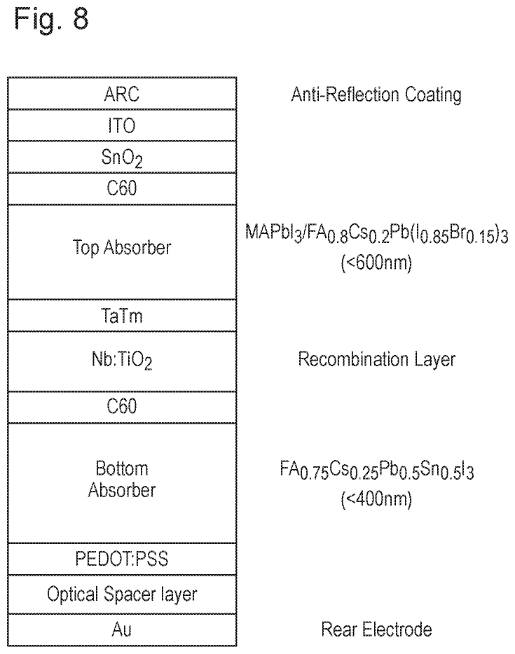

The multi-junction device as described herein may further comprise one or more optical spacer layers. Due to the properties of light, when light reflects off a metalic surface, a node in the waveform is positioned in close proximity to the metalic surface. This means that the optical power density, i.e. optical intensity, will be low in regions close to the metalic reflecting layer. In the devices described herein, a metalic electrode may be used as the rear reflector. However, since the charge extraction layers can be very thin, the second photoactive layer is often in close proximity to this rear reflective metal layer. This therefore implies that the optical power density, and ensuing light absorption, in the rear region of the second photoactive layer is often low. To overcome this problem, an optical spacer layer between the second photoactive layer (and the optional buffer layer) and the second electrode may be included. This optical spacer layer must be highly transparent to light in the wavelength range of the spectral response of the second photoactive material. For example, it may be a transparent conducting oxide, for instance a transparent conducting oxide such as ITO, AZO or FTO. Preferably, the refractive index of the optical spacer layer will be close to that of the second photoactive layer. The optical spacer layer may be TiO₂, metal doped TiO₂ or TiN. An example of a device with an optical spacer layer is shown in FIG. 8.

The multi-junction device as described herein may further comprise a first electrode. The first electrode may comprise a metal (for instance silver, gold, aluminium or tungsten) or a transparent conducting oxide (for instance fluorine doped tin oxide (FTO), aluminium doped zinc oxide (AZO) or indium doped tin oxide (ITO)). Typically the first electrode is a transparent electrode. Thus, the first electrode typically comprises a transparent conducting oxide, preferably FTO, ITO or AZO. The thickness of the layer of a first electrode is typically from 5 nm to 100 nm.

The multi-junction device as described herein may further comprise a second electrode. The second electrode may be as defined above for the first electrode. Typically, the second electrode comprises, or consists essentially of, a metal for instance an elemental metal. Examples of metals which the second electrode material may comprise, or consist essentially of, include silver, gold, copper, aluminium, molybdenum, platinum, palladium, or tungsten. The second electrode may be disposed by vacuum evaporation. The thickness of the layer of a second electrode material is typically from 1 to 250 nm, preferably from 50 nm to 150 nm.

Thus, the multi-junction device as described herein may further comprise a first electrode and a second electrode. Usually, the multi-junction device comprises the following layers in the following order:
first electrode, as described herein;
an optional buffer layer, as described herein;
hole transporting (p-type) layer, as described herein;
an optional interface modifying layer, as described herein,
layer of a first photoactive material, as described herein;
an optional interface modifying layer, as described herein;
electron transporting (n-type) layer, as described herein;
optional buffer layer, as described herein;
charge recombination layer, as described herein;
optional buffer layer, as described herein;
hole transporting (p-type) layer, as described herein;
optional interface modifying layer, as described herein;
layer of a second photoactive material, as described herein;
an optional interface modifying layer, as described herein;
electron transporting (n-type) layer, as described herein;
optional buffer layer, as described herein;
second electrode, as described herein.

Typically, the first electrode comprises a transparent conducting oxide, preferably ITO, AZO or FTO, and the second electrode comprises an elemental metal, preferably silver, gold, molybdenum or tungsten.

In one embodiment, the multi-junction device comprises the following layers in the following order:
first electrode, preferably comprising a transparent conducting oxide as described herein;
hole transporting (p-type) layer, as described herein;
layer of a first photoactive material, wherein said first photoactive material comprises at least one A/M/X material as described herein;
electron transporting (n-type) layer, as described herein;
charge recombination layer, preferably comprising a charge recombination layer material that comprises (a) TiO₂ or metal-doped TiO₂, as described herein, and optionally (b) a transparent conducting oxide, as described herein;
hole transporting (p-type) layer, as described herein;
layer of a second photoactive material, wherein said second photoactive material comprises a compound which is a photoactive semiconductor other than an A/M/X material, as described herein;
electron transporting (n-type) layer, as described herein;
optional optical spacer layer, as described herein;
second electrode, preferably comprising an elemental metal or a transparent conducting oxide as described herein.

The multi-junction device may further comprise optional buffer layers and optional interface modifying layers as described herein. The charge recombination layer may comprise the layer of the charge recombination layer material and one or more additional layers as described herein.

In another embodiment, the multi-junction device comprises the following layers in the following order:
first electrode, preferably comprising a transparent conducting oxide as described herein;
hole transporting (p-type) layer;
layer of a first photoactive material, wherein said first photoactive material comprises at least one A/M/X material as described herein;
electron transporting (n-type) layer;
charge recombination layer, preferably comprising a charge recombination layer material that comprises (a) TiO₂ or metal-doped TiO₂, as described herein, and optionally (b) a transparent conducting oxide, as described herein;
hole transporting (p-type) layer;
layer of a second photoactive material, wherein said second photoactive material comprises at least one A/M/X material as described herein;
electron transporting (n-type) layer;
optional optical spacer layer, as described herein;
second electrode, preferably comprising an elemental metal or a transparent conducting oxide as described herein.

The multi-junction device may further comprise optional buffer layers and optional interface modifying layers as described herein. The charge recombination layer may comprise the layer of the charge recombination layer material and one or more additional layers as described herein.

The multi-junction device may be an optoelectronic device. Optoelectronic devices include photovoltaic devices, photodiodes (including solar cells), phototransistors, photomultipliers, photoresistors, or light emitting devices. Typically, the multi-junction device is a photovoltaic device or a light-emitting device. Preferably, the multi-junction device is a positive-intrinsic-negative (p-i-n) planar heterojunction photovoltaic device.

The multi-junction device may be of the invention may be a multi-junction light emitting devices, where multiple junctions of different band gap light emitting diodes result in a combined white light emission.

Method of Manufacture

The multi-junction devices of the present invention may be manufactured by the sequential deposition of each layer on a substrate. Typically, the substrate is a transparent substrate, such as glass, and each layer is deposited in turn to build up a stack of layers that forms the multi-junction device structure. Some or all of the layers may be deposited by solution phase deposition, for instance gravure coating, slot dye coating, screen printing, ink jet printing, doctor blade coating, spray coating, roll-to-roll (R2R) processing, or spin-coating. Typically, some of the layers are deposited by spin-coating.

For instance, the multi-junction device may be fabricated by
Providing a substrate, typically a transparent substrate such as glass;
Depositing the first electrode, typically comprising a transparent conducting oxide, on the substrate;
Optionally depositing a charge transporting layer, typically a p-type layer;
Depositing a layer of a first photoactive material;
Optionally depositing a charge transporting layer, typically a n-type layer;
Depositing the charge recombination layer;
Optionally depositing a charge transporting layer, typically a p-type layer;
Depositing a layer of a second photoactive material;
Optionally depositing a charge transporting layer, typically a n-type layer;
Depositing the second electrode, typically comprising an elemental metal.

Methods for deposition of n-type and p-type layers, deposition of A/M/X materials, deposition of photoactive semiconductors other than A/M/X materials and deposition of electrodes are well known in the art and may be found in published patent applications WO2013/132236, WO2013/171517, WO2013/171518, WO2013/171520, WO2014/045021, WO2014/191767, WO2014/202965, WO2015/092397, WO2015/140548, WO2016/005758, WO2016/020699, WO2017/060700, WO2017/037448, WO2017/089819, WO2017/153752 and WO2018/193267. The multi-junction devices of the invention can be prepared according to the methods set out in these documents using the materials described herein.

Typically, the first electrode is disposed on the substrate by sputter coating.

Typically, depositing the charge transporting layer comprises forming a solution or dispersion of the n-type or p-type material or n-type or p-type precursor in a solvent, and spin-coating the solution or dispersion onto the layer stack. Usually, the solution treated layer stack is dried to remove the solvent. Removing the solvent may comprise heating the solvent, or allowing the solvent to evaporate.

At least one of the layers of photoactive material comprises at least one A/M/X compound as described herein. Such A/M/X compounds may be deposited on the device stack by disposing at least one film-forming solution comprising one or more A cations, one or more M cations and one or more X anions, as described herein. The film-forming solution may be disposed on the device stack by gravure coating, slot dye coating, screen printing, ink jet printing, doctor blade coating, spray coating, roll-to-roll (R2R) processing, or spin-coating, typically by spin-coating.

The charge recombination layer may be disposed on the substrate by solution-based techniques or other techniques such as vacuum deposition or sputter coating, depending on the choice of charge recombination layer material.

Typically, when the charge recombination layer comprises TiO2, metal-doped TiO2 (for example Nb doped TiO2) or a blend of TiO₂ or metal-doped TiO₂ and a transparent conducting oxide, the charge recombination layer is deposited on the device stack by sputter coating.

Typically, the second electrode is deposited by vacuum deposition.

### EXAMPLES

The advantages of the invention will hereafter be described with reference to some specific examples.

### Example 1

### Optical and Device Modeling

We implemented an optical model (Generalized Transfer Matrix Method) [Charalambos C. Katsidis and Dimitrios I. Siapkas, Applied Optics 41, no. 19 (2002): 3978] and a detailed balance based device model [Kristofer Tvingstedt et al., Scientific Reports 4 (2014): 1-7] to simulate the impact of an index-matched interlayer. The Transfer-Matrix method is a recasting of Maxwell's equations to calculate electromagnetic wave propagation in any stratified medium, such as a solar cell stack. The model fully accounts for interference. It uses the optical constants and thicknesses of the layers to calculate the absorptance A(λ), which is treated as the External Quantum Efficiency (EQE(λ)) of the cell. We then used detailed-balance (assuming state of the art series resistance Rₛ, shunt resistance Rₛₕ, ideality factor n_{id} and Electroluminescence External Quantum Efficiency EQE_{EL}) to calculate a JV curve, thus fully determining device performance.

Optimized ITO Interlayer

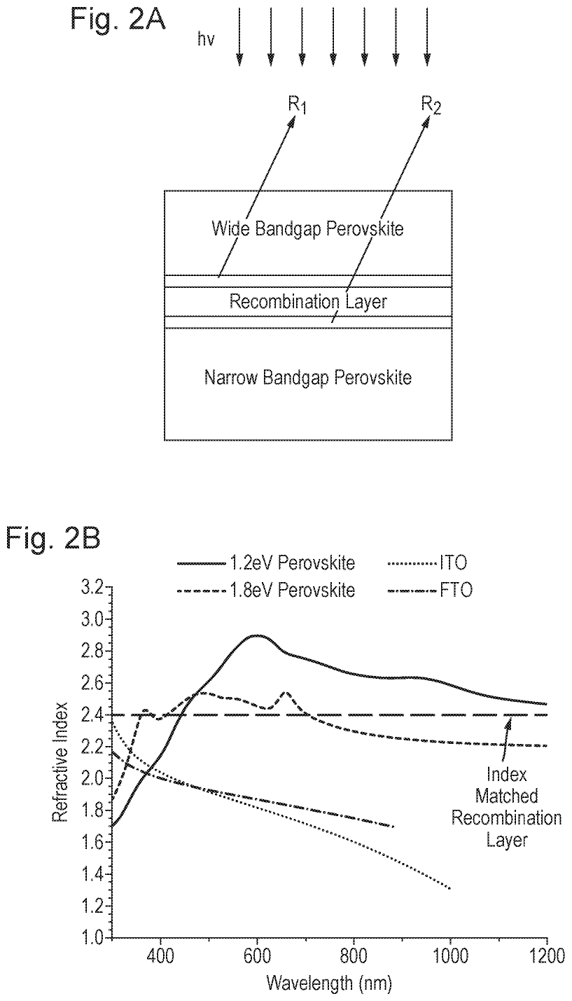

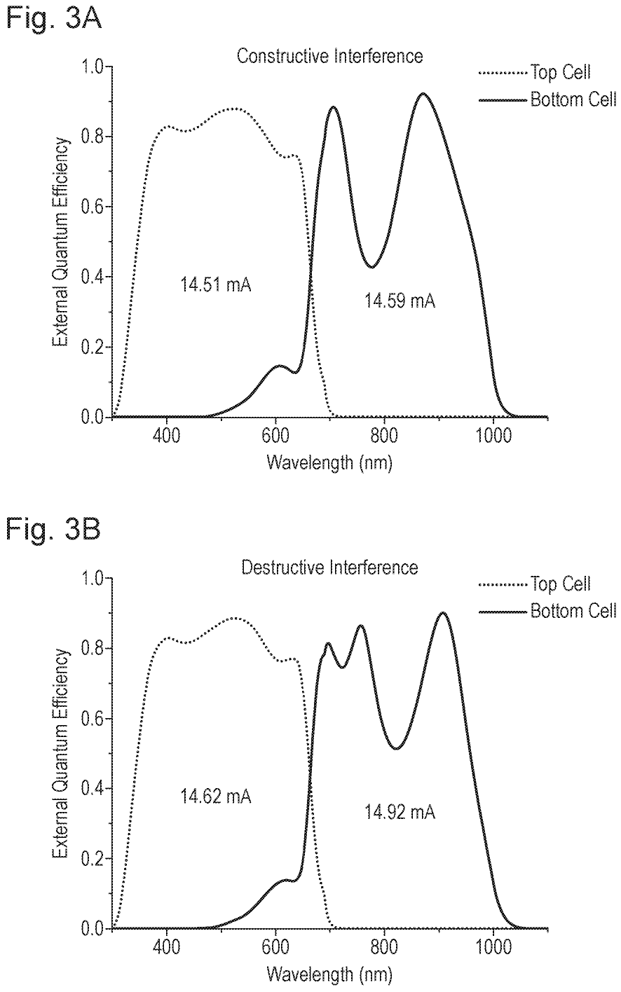

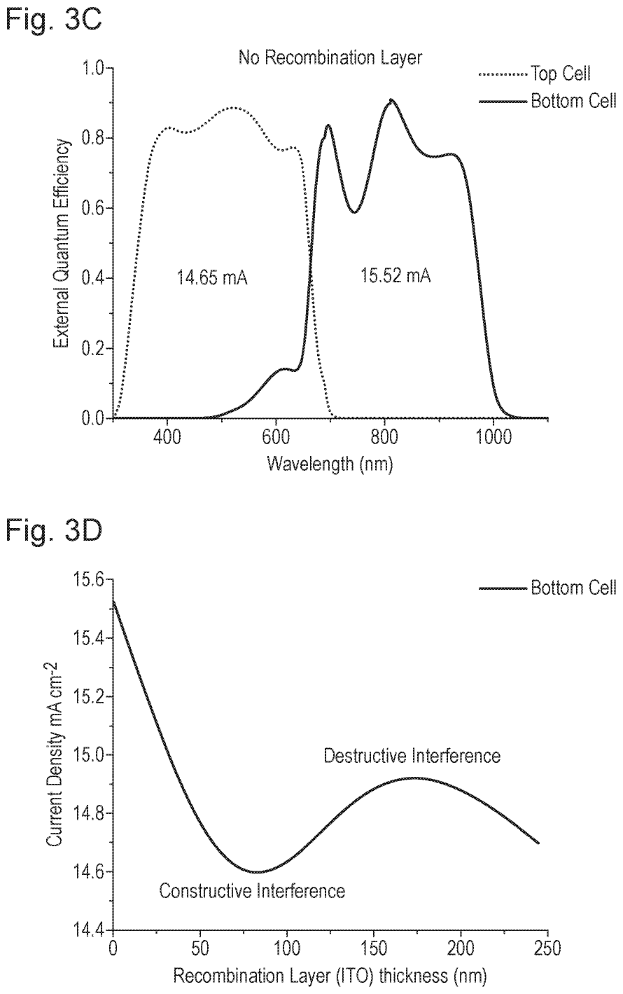

An interlayer works best when the two reflections (FIG. 2a) can interfere destructively. Even with a severely mismatched ITO interlayer, the dip in the EQE can be reduced if the right thickness is chosen. Unfortunately, this optimum thickness falls between 150-200 nm for an ITO interlayer. This is thicker than ideal from a manufacturing and materials use perspective, due to the cost and scarcity of Indium. In addition, there is still significant reflection even under this optimum ITO thickness. A more practical thickness-100-120 nm falls exactly in the region which maximizes reflection. Thus, ITO is optically ill-suited for use as an interlayer. It only serves to aggravate reflection at all thicknesses. Indeed, the tandem is seen to reflect the least when the ITO layer is shrunk to 0 nm. This is of course an impractical thickness if its presence is required for enabling either charge recombination or to act as a solvent barrier. For the solvent-barrier functionality, it is likely that the ITO layer should be in the range of 100 nm in thickness.

Index Matched Recombination Layer

An index matched interlayer would not suffer from the issues that ITO has. Let nₜₒₚ(λ) and n_{bot}(λ) be the refractive indices of the top and bottom absorber respectively. A non-absorbing interlayer of refractive index of n=\sqrt{nₜₒₚ(λ₀)·n_{bot}(λ₀)} would then minimize reflection at λ₀ if its thickness is

$$\frac{λ o}{4 n}$$

The thickness also has to minimize the total reflection over all wavelengths, also taking the incident spectrum into account. However, real interlayers are not entirely transparent, especially if they are electronically doped. This pushes the optimum refractive index for the interlayer towards higher refractive indices, in order to minimize reflectance losses with thinner thickness.

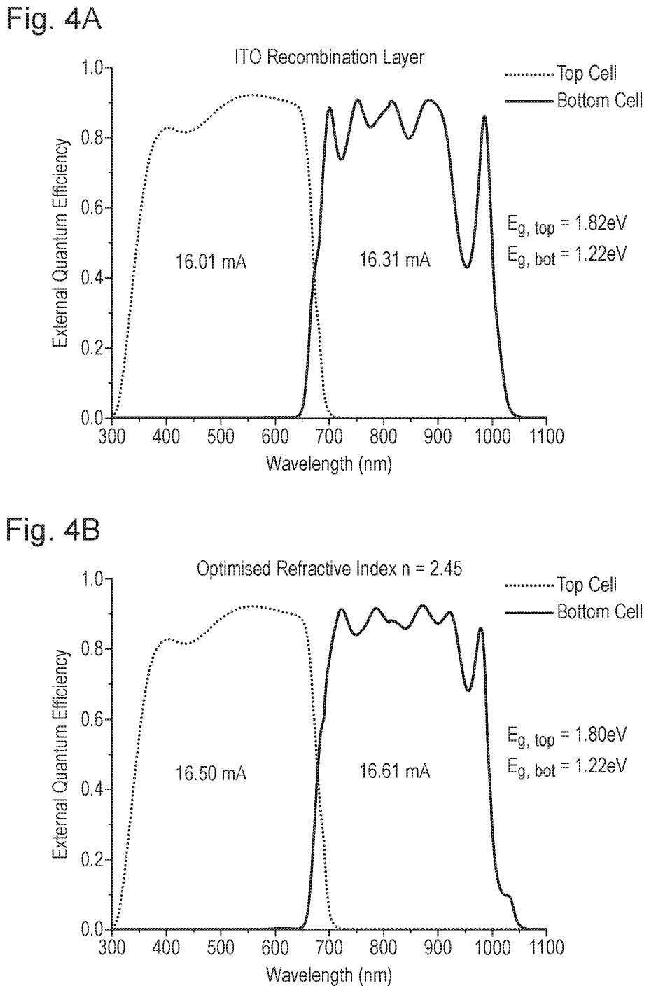

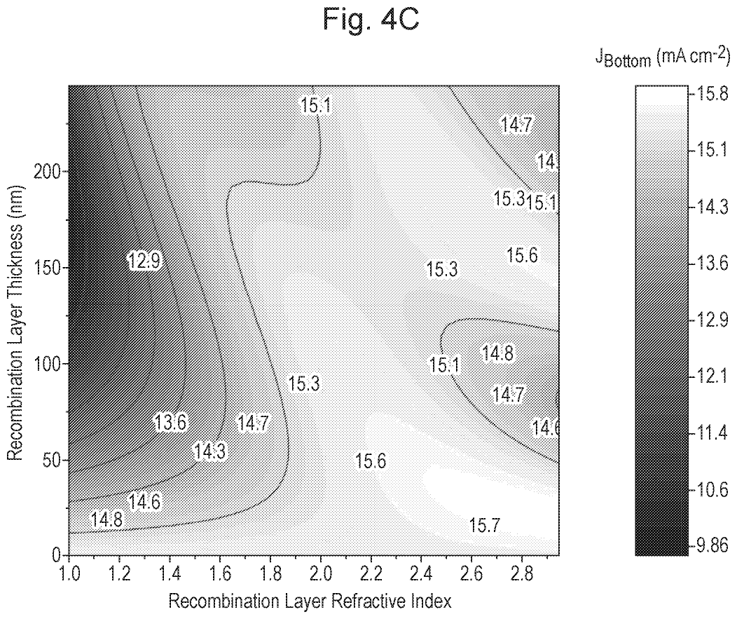

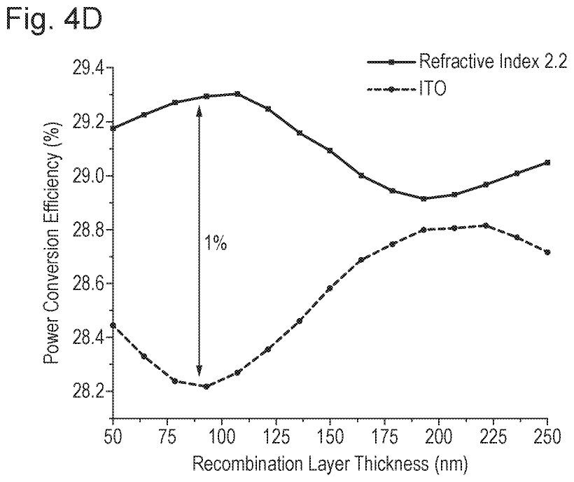

Optical calculations reveal that interlayers with refractive indices of 2.0-2.5 (700-1000 nm) maximize current. In such interlayers, the current is also less sensitive to the thickness of the interlayer chosen. In the model, the power conversion efficiency (PCE) of the tandem perovskite cell using an optimized ITO thickness of 203 nm is estimated to be 28.8%. The best index matched-interlayer (n=2.45, t=50 nm) presents a 0.6% absolute gain, increasing the PCE to 29.38%. However, 203 nm ITO is impractical, as previously explained. The selection of a refractive index of 2.45, I based on the optimum value from the model. However, there are very few real materials which are both highly transparent (wide band gap) and have this high refractive index. A more practical value of ˜2.2, can be achieved by a number of materials. In the more practical scenario of n=2.2 and t=100 nm, the PCE advantage of swapping ITO, for the 2.2 refractive index material is over 1% absolute gain, which is shown in FIG. 4d.

High Refractive Index Materials

As our calculations have shown (FIG. 4), a recombination layer with high refractive index n(850 nm)>2.0 can give increase the PCE by one 1% absolute.

Such a recombination layer would need to satisfy:

High Refractive Index (n>2.0) where the bottom-cell absorbs (650-1100 nm).

Low absorption co-efficient (α<10³ cm⁻¹) between 650-1100 nm. Wide bandgap semiconductors are suitable.

Low resistivity (<500 Ωcm) (to enable low loss recombination of electrons and holes)

In short, this is similar to the class of materials suitable for making TCOs. Unfortunately, high-refractive index TCOs are rare due to the aforementioned empirical rule: Wide-bandgap semiconductors tend to have low refractive indices. There are some exceptional ceramics with high-refractive index: TiO₂ [n_{900 nm}=2.3], SrTiO₃ [2.33], Cr₂O₃ [2.5], CuCrO₂ [2.6], ZnS [2.3], ZrO₂ [2.12], AlN [2.1], GaN [2.3].

TiO₂ is a suitable high-index alternative to ITO or FTO. Specifically when doped with Nb, TiO₂ has a high conductivity, and absorb less light across the visible to IR spectrum than ITO. The low temperature processed phase, rutile TiO₂, has suitable conductivity and mobility for a recombination layer. Also, the low temperature processing is advantageous since organic-inorganic perovskite materials do not tolerate high temperatures. Unlike in an electrode, there is no necessity for long range lateral conduction in a recombination layer, and in fact having low lateral conduction is an advantage, due to minimizing the risk of short-circuiting the device through the interlayer. This is especially important when turning the monolithic deposited layers into a module in which series interconnection between the top electrode and bottom electrode is required. When considering the series resistance perpendicular to the substrate through the cell, even a resistivity as high as 10⁴ Ωcm will cause a negligible drop in voltage of about 1 mV in a 100 nm thick recombination layer. Nb:TiO₂ films have been achieved with resistivity of 6-10⁻¹ Ωcm, by sputtering at room temperature. [Ben Jemaa et al., Journal of Materials Science: Materials in Electronics 27, no. 12 (2016): 13242-48].

Nb: TiO₂ Interlayer

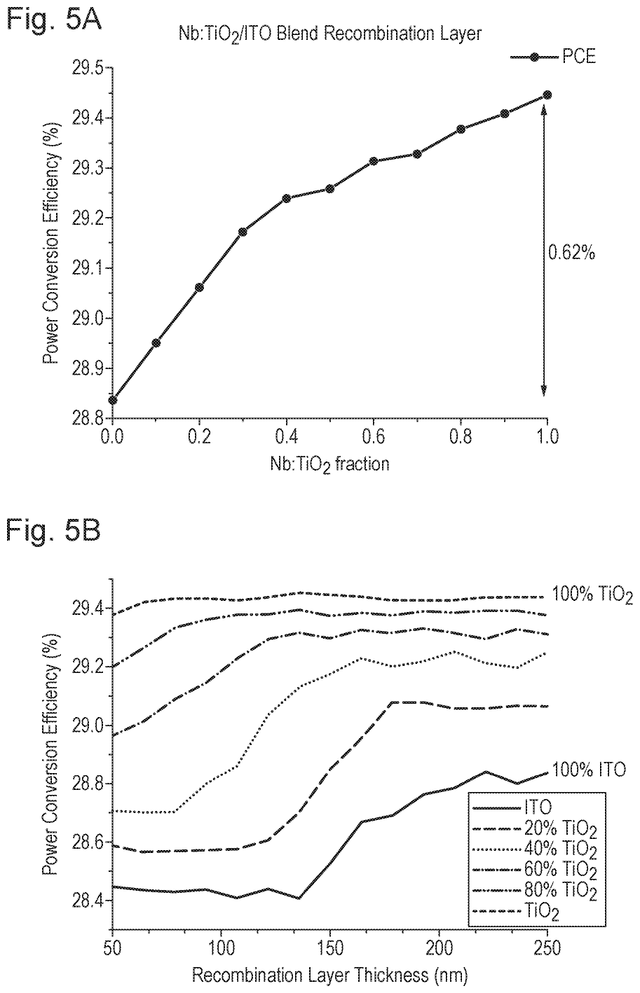

Nb:TiO₂ is a promising high-refractive index interlayer. A Nb:TiO₂/ITO blend could be also used to tune the refractive-index, and also improve electronic contact, where the advantageous electronic properties of ITO may be combined with the optical properties of TiO₂. We calculate the performance of tandems with Nb:TiO₂/ITO blended interlayers (FIG. 5). At a thickness of 100 nm, 60/40 Nb:TiO₂/ITO blend recombination layer gives a 0.8% absolute PCE gain.

Improved Angular Insensitivity

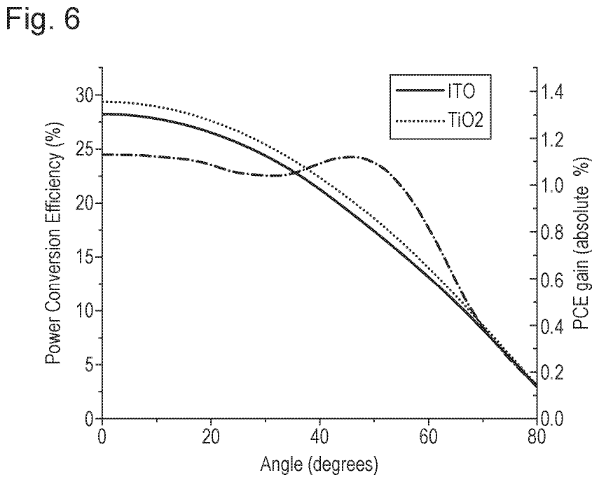

The lab-measured PCE paints an incomplete picture about the performance of a cell in the real world. Laboratory measurements are typically done under a simulated direct-incidence AM1.5 spectrum. The cell would also be optimized for performance under such conditions. However, the spectral composition of sunlight can vary significantly depending on location, time, cloud cover, humidity and dust. In addition, the angle of incidence changes through the day and the year. On a cloudy or foggy day, most of the incident light would be diffuse, impinging on the panel from all angles. At direct-incidence, the TiO₂ index-matched stack shows a gain of 1.10% (absolute) over the ITO stack. An improvement in power-conversion efficiency is seen over the entire range of incidence angles (FIG. 6). This will be particularly important in overcast locations, like the United Kingdom, where diffuse light can sometimes dominate.

Lowered Sensitivity to Thickness Variation

In principle, these optimum thicknesses for tandem cell layers can be calculated, using a transfer-matrix based optical model. In practice, this exact optimum cannot be achieved since there is random variation in thickness during manufacturing. This effect will cause most real cells will have efficiencies lower than the optimum. Modelling shows that index-matched cells are more insensitive to thickness variation than unmatched cells. This will result in a corresponding increase

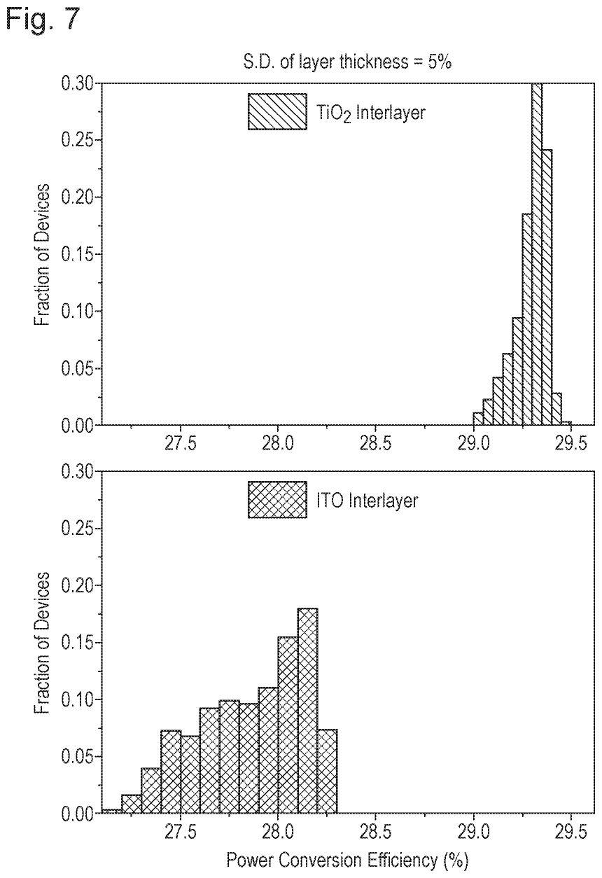

We simulate a batch of 1000 cells with absorber and recombination layer thicknesses distributed normally around the optimum with 5% standard deviation (FIG. 7). For the batch of cells with ITO (28.28% optimum), the average PCE is 27.86%—a 0.42% drop. For the cells with TiO₂ (29.46% optimum), the average PCE is 29.23%—a 0.16% drop.

### Example 2—Fabrication of a NbTiO₂ Thin Film

80 nm NbTiO₂ films were formed on silicon and glass substrates by sputter coating from a 4% Nb doped TiO₂ target. The substrates were cleaned as follow prior to deposition.

Silicon: rinsed successively in acetone and IPA and blown dry.

Glass: Sonicated successively for 2 mins each in DECON90, deionised water, acetone and IPA, then blown dry.

First a cleaning recipe was run with the following settings:
Initial chamber pump down to 9e-6 Torr
Argon set at 18 SCCM (standard cubic centimeters per minute)
100 W HIPIMs (high-power impulse magnetron sputtering) on 4 inch target
Average current 800 mA
Pulse frequency 750 Hz
Pulse width 50 μs
Pressure setpoint 5 mTorr
Sputtered for 20 min

Then the deposition was run with the following deposition run settings:
Initial chamber pump down to 2e-6 Torr
Substrate rotation 10 rpm
Sample stage at 30° C.
Argon set at 18 SCCM
100 W HIPIMs on 4 inch target
Average current 800 mA
Pulse frequency 750 Hz
Pulse width 50 μs
Pressure setpoint 5 mTorr
Sputter for 30.5 min for surface cleaning
O₂ set at 6 SCCM
Wait 19.5 min
Open shutter and drop stage to 4 inches
4 hour deposition time
sample stage temperature was ramped up to 70° C. for the last hour of deposition

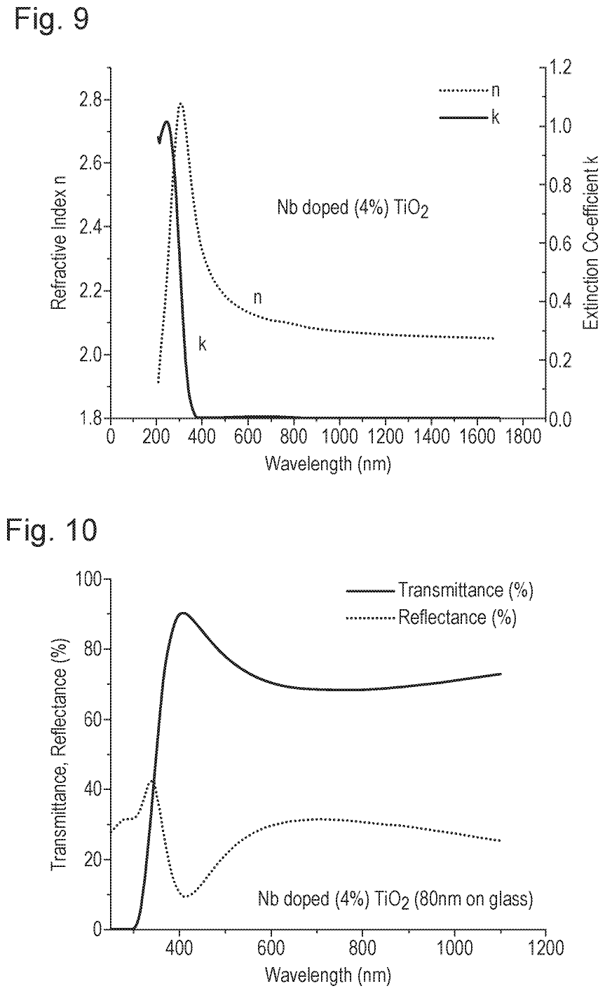

Optical constants n and k were established using ellipsometry. The ellipsometry data was measured on a 80 nm sputtered Nb doped (4%) TiO₂ film on a silicon wafer. The instrument used was a J. A. Woollam RC2 Ellipsometer. The results of the testing are shown in in FIG. 9. The data in FIG. 9 show that the refractive index, n, of the layer was greater than 2 for all wavelengths between 500 and 1200 nm.

Transmittance and reflectance data of an 80 nm thick Nb doped (4%) TiO₂ thin film sputtered on glass were collected using a Perkin Elmer 1050 with an integrating sphere accessory. and are shown in FIG. 10. Transmittance was above 60% for all wavelengths between 400 and 1200 nm.

1. A multi-junction device comprising
a) a first photoactive region comprising a layer of a first photoactive material,
b) a second photoactive region comprising a layer of a second photoactive material, and
c) a charge recombination layer disposed between the first and second photoactive regions, wherein the charge recombination layer comprises a charge recombination layer material,
wherein one of the first and second photoactive materials comprises at least one A/M/X material;
wherein the other of the first and second photoactive materials comprises at least one A/M/X material or a compound which is a photoactive semiconductor other than an A/M/X material;
wherein each A/M/X material is a crystalline compound of formula (I)
[A]ₐ[M]_{b}[X]_{c} (I)
wherein:
[A] comprises one or more A cations;
[M] comprises one or more M cations which are metal or metalloid cations;
[X] comprises one or more X anions;
a is a number from 1 to 6;
b is a number from 1 to 6; and
c is a number from 1 to 18; and
wherein the charge recombination layer material has a refractive index, n(λ), at a wavelength, λ, of at least 2, wherein λ is a wavelength of from 500 nm to 1200 nm.

2. A multi-junction device according to claim 1 wherein the charge recombination layer material has a refractive index n(λ_{A}) at a wavelength λ_{A} and the first photoactive material has a refractive index n₁(λ_{A}) at the wavelength λ_{A}, wherein n₁(λ_{A}) is less than n(λ_{A}) and wherein λ_{A} is a wavelength of from 500 nm to 1200 nm which is the same as or different from λ.

3. A multi-junction device according claim 1 wherein the charge recombination layer material has a refractive index n(λ_{A}) at a wavelength λ_{A} and the second photoactive material has a refractive index n₂(λ_{A}) at the wavelength λ_{A}, wherein n₂(λ_{A}) is greater than n(λ_{A}) and wherein λ_{A} is a wavelength of from 500 nm to 1200 nm which is the same as or different from λ.

4. A multi-junction device according to claim 1 wherein the charge recombination layer material has a refractive index n(λ_{A}) at a wavelength λ_{A}, the first photoactive material has a refractive index n₁(λ_{A}) at the wavelength λ_{A} and the second photoactive material has a refractive index n₂(λ_{A}) at the wavelength λ_{A}, wherein n₁(λ_{A}) is less than n(λ_{A}), and n₂(λ_{A}) is greater than n(λ_{A}), and wherein λ_{A} is a wavelength of from 500 nm to 1200 nm which is the same as or different from λ.

5. A multi-junction device according to any one of claims 2 to 4 wherein λ_{A} and λ are the same wavelength.

6. A multi-junction device according to any one of the preceding claims wherein the refractive index n(λ) of the charge recombination layer material at the wavelength λ is less than 3.5, optionally less than or equal to 3, and more particularly less than or equal to 2.5.

7. A multi-junction device according to any one of the preceding claims wherein the charge recombination layer material is semi-transparent, optionally wherein the charge recombination layer material has a mean optical transparency in the visible to near infrared range of the spectrum which is equal to or greater than about 50%.

8. A multi-junction device according to any one of the preceding claims wherein the charge recombination layer material comprises a wide band-gap semiconductor.

9. A multi-junction device according to any one of the preceding claims wherein the first photoactive material has a band gap Eg₁ and wherein the second photoactive material has a band gap Eg₂, wherein Eg₁ is greater than Eg₂.

10. A multi-junction device according to any one of the preceding claims wherein the first photoactive material has a band gap Eg₁ and wherein the charge recombination layer material has a band gap Eg, wherein Eg is greater than Eg₁.

11. A multi-junction device according to any one of the preceding claims wherein the charge recombination layer material has a band gap Eg, the first photoactive material has a band gap Eg₁, and the second photoactive material has a band gap Eg₂, wherein Eg is greater than Eg₁ and Eg₁ is greater than Eg₂, optionally wherein Eg is at least 2.0 eV, more particularly wherein Eg is at least 3.0 eV and Eg₁ is 2.0 eV or less.

12. A multi-junction device according to any one of the preceding claims wherein the charge recombination layer has a thickness of at least 5 nm, optionally a thickness of from 20 to 300 nm, more particularly a thickness of from 50 to 200 nm, or a thickness of from 75 to 150 nm.

13. A multi-junction device according to any one of the preceding claims wherein the charge recombination layer has a thickness in nm of
$$\frac{λ o}{4 n} \pm 50 \% ,$$
wherein λₒ is a wavelength of from 500 nm to 1200 nm which is the same as or different from λ, and n is the refractive index of the charge recombination layer material at λₒ, optionally wherein λₒ is the same as λ.

14. A multi-junction device according to any one of the preceding claims wherein the wavelength λ is a wavelength of from 500 and 1100 nm, optionally a wavelength of from 600 to 1200 nm, optionally a wavelength of from 600 and 1000 nm, more particularly a wavelength of from 800 nm to 1000 nm, for instance a wavelength of 850 nm.

15. A multi-junction device according to any one of the preceding claims wherein one of the first and second photoactive materials comprises at least one A/M/X material as defined in claim 1 and the other of the first and second photoactive materials comprises a compound which is a photoactive semiconductor other than an A/M/X material,
preferably wherein the first photoactive material comprises at least one crystalline A/M/X material as defined in claim 1, and the second photoactive material comprises a compound which is a photoactive semiconductor other than an A/M/X material.

16. A multi-junction device according to claim 15 wherein the compound which is a photoactive semiconductor comprises a chalcogenide anion.

17. A multi-junction device according to claim 15 or claim 16 wherein the photoactive semiconductor compound is selected from copper zinc tin chalcogenides, antimony chalcogenides, bismuth chalcogenides, copper indium gallium chalcognides, cadmium chalcogenides, iron chalcogenides and lead chalcogenides;
optionally wherein the photoactive semiconductor compound is selected from copper indium gallium selenide (CIGS), copper indium sulphide (CIS), copper indium sulphide selenide (CIG(S)Se), cadmium telluride (CdTe), cadmium telluride selenide (CdTeₓSe₁₋ₓ, where 0<x<1), cadmium telluride sulfide (CdTeₓS₁₋ₓ, where 0<x<1), copper zinc tin sulphide (CZTS), copper zinc tin selenide (CZTSe), copper zinc tin sulphide selenide (CZTSSe), antimony sulphide, antimony selenide, bismuth sulphide, bismuth selenide, iron sulphide, lead sulphide, lead selenide, cadmium sulphide, and cadmium selenide;
more particularly wherein the photoactive semiconductor compound is selected from copper indium gallium selenide (CIGS), copper indium sulphide (CIS), copper indium sulphide selenide (CIG(S)Se), cadmium telluride (CdTe), cadmium telluride selenide (CdTeₓSe₁₋ₓ, where 0<x<1), cadmium telluride sulfide (CdTeₓS₁₋ₓ, where 0<x<1), copper zinc tin sulphide (CZTS), copper zinc tin selenide (CZTSe) and copper zinc tin sulphide selenide (CZTSSe).

18. A multi-junction device according to any one of claims 1 to 14 wherein the first photoactive material comprises at least one first A/M/X material as defined in claim 1, and the second photoactive material comprises at least one second A/M/X material as defined in claim 1,
optionally wherein the at least one first and second crystalline A/M/X materials are different.

19. A multi-junction device according to any one of the preceding claims wherein the charge recombination layer material comprises a metal oxide, a metal nitride or a metal sulfide,
optionally wherein the material in the charge recombination layer comprises TiO₂, metal doped-TiO₂, SrTiO₃, BaTiO₃, Cr₂O₃, CuCrO₂, ZnS, ZrO₂, TiN, AlN and GaN,
more particularly wherein the material in the charge recombination layer comprises TiO₂ or metal-doped TiO₂.

20. A multi-junction device according to any one of the preceding claims wherein the charge recombination layer material comprises (a) TiO₂ or metal-doped TiO₂ and (b) a transparent conducting oxide,
optionally wherein the charge recombination layer material comprises a blend of (a) and (b);
more particularly wherein the transparent conducting oxide is indium tin oxide (ITO).

21. A multi-junction device according to claim 20, wherein the TiO₂ or metal-doped TiO₂ is at least 20% by volume of the total volume of the transparent conducting oxide and the TiO₂ or metal-doped TiO₂,
optionally at least 50% by volume of the total volume of the transparent conducting oxide and the TiO₂ or metal-doped TiO₂,
more particularly at least 80% by volume of the total volume of the transparent conducting oxide and the TiO₂ or metal-doped TiO₂.

22. A multi-junction device according to any one of claims 1 to 19 wherein the charge recombination layer material consists essentially of or consists of TiO₂ or metal-doped TiO₂,
preferably wherein the charge recombination layer material consists essentially of or consists of metal-doped TiO₂.

23. A multi-junction device according to any one of claims 19 to 22, wherein the charge recombination layer material comprises metal-doped TiO₂ wherein the metal is a transition metal,
optionally wherein the metal is selected from Ta, V and Nb,
more particularly wherein the metal is Nb.

24. A multi-junction device according to claim 23, wherein the metal in the metal-doped TiO₂ is present in an amount of at least 0.5% by weight of the total weight of the metal-doped TiO₂,
optionally wherein the metal in the metal-doped TiO₂ is present in an amount of from 1 to 10% by weight of the total weight of the metal-doped TiO₂,
more particularly wherein the metal in the metal-doped TiO₂ is present in an amount of from 2 to 6% by weight of the total weight of the metal-doped TiO₂.

25. A multi-junction device according to any one of claims 19 to 24, wherein the TiO₂ in is in the rutile phase.

26. A multi-junction device according to any one of the preceding claims, wherein [A] comprises one or more A cations including at least one organic cation.

27. A multi-junction device according to any one of the preceding claims, wherein each A cation is selected from: an alkali metal cation; a cation of the formula [R₁R₂R₃R₄N]⁺, wherein each of R₁, R₂, R₃, R₄ is independently selected from hydrogen, unsubstituted or substituted C₁₋₂₀ alkyl, and unsubstituted or substituted C₆₋₁₂ aryl, and at least one of R₁, R₂, R₃ and R₄ is not hydrogen; a cation of the formula [R₅R₆N═CH—NR₇R₈]⁺, wherein each of R₅, R₆, R₇ and R₈ is independently selected from hydrogen, unsubstituted or substituted C₁₋₂₀ alkyl, and unsubstituted or substituted C₆₋₁₂ aryl; and C₁₋₁₀ alkylamammonium, C₂₋₁₀ alkenylammonium, C₁₋₁₀ alkyliminium, C₃₋₁₀ cycloalkylammonium and C₃₋₁₀ cycloalkyliminium, each of which is unsubstituted or substituted with one or more substituents selected from amino, C₁₋₆ alkylamino, imino, C₁₋₆ alkylimino, C₁₋₆ alkyl, C₂₋₆ alkenyl, C₃₋₆ cycloalkyl and C₆₋₁₂ aryl;
preferably wherein each A cation is selected from Cs⁺, Rb⁺, methylammonium, ethylammonium, propylammonium. butylammonium, pentylammoium, hexylammonium, septylammonium, octylammonium, tetramethylammonium, formamidinium, 1-aminoethan-1-iminium and guanidinium.

28. A multi-junction device according to any one of the preceding claims, wherein [M] comprises two or more different M cations.

29. A multi-junction device according to any one of the preceding claims wherein each M cation is a dication,
optionally wherein each M cation is selected from Ca²⁺, Sr²⁺, Cd²⁺, Cu²⁺, Ni²⁺, Mn²⁺, Fe²⁺, Co²⁺, Pd²⁺, Ge²⁺, Sn²⁺, Pb²⁺, Yb²⁺ and Eu²⁺,
particularly Sn²⁺, Pb²⁺, Cu²⁺, Ge²⁺, and Ni²⁺; and
more particularly Sn²⁺ and Pb²⁺.

30. A multi-junction device according to any one of the preceding claims wherein each X anion is a halide, optionally wherein [X] comprises two or more different halide anions.

31. A multi-junction device according to any one of the preceding claims wherein the compound of formula [A]ₐ[M]_{b}[X]_{c} is a compound of formula [A][M][X]₃, wherein [A], [M] and [X] are as defined in claims 1 and 25 to 29.

32. A multi-junction device according to any one of the preceding claims wherein the photoactive regions each further comprise one or more charge transporting layers,
optionally wherein each photoactive region further comprises an electron transporting (n-type) layer and a hole transporting (p-type) layer,
more particularly wherein each photoactive region comprises the layer of a photoactive material disposed between an electron transporting (n-type) layer and a hole transporting (p-type) layer.

33. A multi-junction device according to any one of the preceding claims further comprising an optical spacer layer,
preferably wherein the optical spacer layer comprises a transparent conducting oxide, TiO₂, metal-doped TiO₂ or TiN.

34. A multi-junction device according to any one of the preceding claims further comprising a first electrode and a second electrode;
optionally wherein the first electrode comprises a transparent conducting oxide, and
optionally wherein the second electrode comprises an elemental metal.

35. A multi-junction device according to any one of the preceding claims wherein the multi-junction device is an optoelectronic device, optionally wherein the optoelectronic device is a photovoltaic device or a light-emitting device.
